(19) United States
(12) Patent Application Publication
(10) Pub. No.: US 2021/0159426 A1
(43) Pub. Date: May 27, 2021

(54) PEROVSKITE COMPOSITIONS COMPRISING MIXED SOLVENT SYSTEMS

(71) Applicant: The University of North Carolina at Chapel Hill, Chapel Hill, NC (US)

(72) Inventors: Jinsong Huang, Chapel Hill, NC (US); Yehao Deng, Chapel Hill, NC (US)

(21) Appl. No.: 17/045,050

(22) PCT Filed: Apr. 1, 2019
(86) PCT No.: PCT/US2019/025237

§ 371 Date: Oct. 2, 2020

Related U.S. Application Data
(60) Provisional application No. 62/651,298, filed on Apr. 2, 2018.

(51) Int. Cl. H01L 51/00; C09D 11/037; C09D 11/033; C09D 11/52; H01G 9/00; H01G 9/20; H01L 51/42; H01L 51/44

(52) U.S. Cl. CPC H01L 51/0077; C09D 11/037; C09D 11/033; C09D 11/52; H01L 51/441; H01G 9/2009; H01G 9/2018; H01L 51/0007; H01L 51/4253; H01G 9/0036

(57) ABSTRACT

Described herein is an ink solution, comprising a composition of formula (I): ABX₃(I), wherein A comprises at least one cation selected from the group consisting of methylammonium, tetramethylammonium, formamidinium, cesium, rubidium, potassium, sodium, butylammonium, phenethylammonium, phenylammonium, and guanidinium; B comprises at least one divalent metal; and X is at least one halide; and a mixed solvent system comprising two or more solvents selected from the group consisting of dimethyl sulfoxide, dimethylformamide, γ-butyrolactone, 2-methoxyethanol, and acetonitrile. Methods for producing poly-crystalline perovskite films using the ink solutions described herein and the use of the films in photovoltaic and photoactive applications are additionally described.

### CROSS-REFERENCE TO RELATED APPLICATIONS

This application claims the benefit of priority to U.S. Provisional Application No. 62/651,298, filed Apr. 2, 2018, which is herein incorporated by reference in its entirety for all purposes.

### GOVERNMENT INTEREST

This invention was made with government support under Grant No. N000014-17-1-2619 awarded by The Office of Naval Research. The Government has certain rights in the invention.

### FIELD OF THE INVENTION

The presently disclosed subject matter relates generally to perovskite compositions comprising a mixed solvent system. The perovskite compositions can be used in the fabrication of polycrystalline films for use in photovoltaic or photoactive devices.

### BACKGROUND

Perovskite solar cells have shown rapidly improved power conversion efficiency (PCE) and stability in recent years.¹⁻³ The certified PCEs for small devices already rival those of other thin film photovoltaic technologies.⁴ However, one challenge before commercialization is transferring these technologies into the marketplace using high throughput film deposition techniques for module fabrication.⁵⁻⁷ A “high electrification” future in 2050 would demand an annual photovoltaics (PV) installation of 1780 GW,⁸ while the global installation in 2017 is only 99.1 GW.⁹ It requires a rapid expansion of PV manufacturing, which may be fulfilled by perovskite PV due to its low cost and rapid solution processing. One gigawatt of power needs over 6.7 million square meters of solar panels with 18% efficiency. These thin films of half a micrometer (μm) thick need to be deposited at a fast speed to be economically competitive. Therefore, fast and safe deposition of perovskite films is critically important. Deposition at ambient conditions is preferred, because it allows easy integration into mature industrial processes and reduces safety issues when flammable solvents are involved. However, from a material growth kinetics point of view, rapid crystallization at low temperature generally results in perovskite films with low crystallinity, high defect density, and small grains, which reduce both the efficiency and stability of perovskite solar cells. Therefore, there exists a need in the art to reconcile the conflict between fast-deposition induced low crystallinity and the desire for large-grains with high crystallinity for high efficiency and stability. The subject matter described herein addresses this problem.

### BRIEF SUMMARY

In one aspect, the presently disclosed subject matter is directed to an ink solution, comprising a composition of formula (I):

ABX₃ (I)

wherein A comprises at least one cation selected from the group consisting of methylammonium, tetramethylammonium, formamidinium, cesium, rubidium, potassium, sodium, butylammonium, phenethylammonium, phenylammonium, and guanidinium;
B comprises at least one divalent metal; and
X is at least one halide; and
a mixed solvent system comprising two or more solvents selected from the group consisting of dimethyl sulfoxide, dimethylformamide, γ-butyrolactone, 2-methoxyethanol, and acetonitrile.

In another aspect, the presently disclosed subject matter is directed to a film comprising a polycrystalline perovskite composition of formula (I):

ABX₃ (I)

wherein A comprises at least one cation selected from the group consisting of methylammonium, tetramethylammonium, formamidinium, cesium, rubidium, potassium, sodium, butylammonium, phenethylammonium, phenylammonium, and guanidinium;

B comprises at least one divalent metal; and

X is at least one halide;

wherein the film of said polycrystalline perovskite composition has large grain sizes in a range of about 10 nm to 1 mm, a thickness in a range of about 10 nm to 1 cm, and a compact, pin-hole free, and uniform structure with an area of at least 25 cm².

In another aspect, the presently disclosed subject matter is directed to a solar cell, solar panel, light emitting diode, photodetector, x-ray detector, field effect transistor, memristor, or synapse comprising the polycrystalline perovskite films fabricated by the methods described herein.

### BRIEF DESCRIPTION OF THE DRAWINGS

FIG. 1A shows photographs of dissolution of PbI₂: MAI=1:1 and PbI₂ alone by GBL, 2-ME, ACN, DMSO and DMF solvents at nominal mole concentration of 1 M.

FIG. 1B shows UV-vis absorption spectra of MAPbI₃ solutions prepared from different solvents.

FIG. 1C shows vapor pressure and donor number (D_{N}) of the five solvents studied and D_{N} of iodide ion.

FIG. 2A is a photographic image of a MAPbI₃ solution prepared by dissolving in ACN/2-ME and then heating to 80° C. Black perovskite crystals formed at 80° C.

FIG. 2B is a photographic image of a MAPbI₃ solution prepared by dissolving in 2-ME and then heating to 80° C. Black perovskite crystals formed at 80° C.

FIG. 2C is a photographic image of the Inverse temperature crystallization of MAPbI₃ in 2-ME solvent at 70° C.

FIG. 3A is an illustration for N₂-knife-assisted blade coating of perovskite films at 99 mm/s at room temperature using coordination tailored ink (the inset shows the as-coated ink, perovskite/intermediate film, and perovskite film).

FIG. 3B shows an as-coated perovskite film on a 15×15 cm²flexible substrate.

FIG. 3C is a photograph image of a ˜10×36 cm²perovskite submodule. A quarter coin is placed at the edge for scale.

FIG. 3D is a schematic illustrating the drying of ink into perovskite/intermediate film and full crystallization of perovskite film with annealing at 70° C. VNCS: volatile non-coordinating solvent. NVCS: non-volatile coordinating solvent.

FIG. 4A shows XRD spectra of as-coated films deposited from DMF, GBL, or 2-ME based solutions mixtures after N₂-knife assisted drying.

FIG. 4B shows XRD spectra of annealed perovskite films prepared with different solvent mixtures.

FIG. 4C shows XRD spectra of as-coated perovskite films from different solvent or solvent mixtures after N₂-knife assisted drying.

FIG. 4D shows XRD spectra of annealed perovskite films prepared with different solvent mixtures.

FIG. 5A shows an SEM image of N₂ knife assisted blade coated perovskite films using DMF as solvent.

FIG. 5B shows an SEM image of N₂ knife assisted blade coated perovskite films using GBL as solvent.

FIG. 5C shows an SEM image of N₂ knife assisted blade coated perovskite films using 2-ME as solvent.

FIG. 5D shows an SEM image of N₂ knife assisted blade coated perovskite films using ACN/2-ME as solvent.

FIG. 5E shows an SEM image of N₂ knife assisted blade coated perovskite film with GBL as an additive.

FIG. 5F shows SEM images of perovskite films prepared with different solvent or solvent mixtures.

FIG. 5G shows cross-sectional SEM images of perovskite films prepared with different solvent or solvent mixtures.

FIG. 6A shows allowed coating speeds for obtaining high quality large area perovskite films as a function of different solvents or solvent mixtures in air knife assisted blade coating experiments.

FIG. 6B shows maximum coating speeds for obtaining high quality large area perovskite films when different solvents are applied in the N₂-knife assisted blade coating process.

FIG. 7A shows the J-V curve of a small area perovskite solar cell fabricated with a N₂-assisted room temperature blade coating method.

FIG. 7B shows the I-V curve of the champion perovskite module.

FIG. 7C shows the distribution of efficiencies of 18 modules fabricated consecutively.

FIG. 7D shows the long term operational stability of an encapsulated perovskite module loaded at maximum power point under 1 sun equivalent illumination.

FIG. 7E shows averaged power conversion efficiencies of perovskite modules measured at different temperatures from 25° C. to 85° C. with a fitted temperature coefficient of −0.13%/° C. The efficiency of a typical silicon module in the market is also added for reference, which has an efficiency of 17% at 25° C. and a temperature coefficient of −0.44%/° C.

FIG. 7F shows the efficiencies of a perovskite module with one sub-cell going through 58 cycles of shading/de-shading. The inset shows schematically how shading is applied over one sub-cell.

FIG. 8A is a schematic illustration for the efficiency uniformity testing over a perovskite module.

FIG. 8B shows the efficiencies distribution of 16 sub-cells in a perovskite module.

FIG. 8C shows the efficiencies distribution of 7 positions from one end to the other in a sub-cell in the perovskite module.

FIG. 9 shows the NREL certification of a perovskite submodule with aperture area of 63.7 cm² and stabilized efficiency of 16.4%.

FIG. 10A shows I-V scanning of a module measured at different temperatures from 25° C. to 85° C.

FIG. 10B shows the stabilized photocurrent output at a respective maximum power point of a module measured at different temperatures from 25° C. to 85° C.

FIG. 10C shows the open circuit voltage of the module measured at different temperatures, giving a fitted temperature coefficient of −0.13%/° C.

FIG. 11A is a schematic illustration of applying shading and then removing shading over one sub-cell in a perovskite module.

FIG. 11B is a photocurrent output of the module before, during and after shading. The bias was kept at 13.2 V, which is the maximum power point before shading.

FIG. 11C shows I-V curves of the module in FIG. 14B before, during and after shading.

FIG. 11D shows I-V curves of another module during 58 cycles of shading/de-shading.

FIG. 12 shows the measured reverse bias on a single sub-cell from a module at −60 mA bias in dark after breakdown.

FIG. 13 is a photograph of a ˜360 cm² perovskite submodule charging a cell phone. The voltage output was converted to ˜5 V (5.2 V as shown by the digits) by a voltage controller to meet the cell phone charging standards.

FIG. 14A is a schematic illustrating air knife assisted blade coating of a perovskite film.

FIG. 14B is a photograph image of an as-coated perovskite film.

FIG. 14C illustrates drying of the perovskite precursor ink and crystallization of the perovskite.

FIG. 15A shows XRD patterns of air-knife-assisted, as-coated, perovskite films from DMSO, DMF, GBL, 2-ME/ACN and 2-ME solvent.

FIG. 15B shows SEM images of as-coated perovskite films from 2-ME/CAN and 2-ME/CAN/DMSO with and without air-knife assisted drying.

FIG. 15C shows XRD spectra for samples of 2-Me/ACN without DMSO after annealing (top pattern), 2-ME/ACN with DMSO after annealing, and 2-ME/CAN with DMSO (center pattern), after air-knife assisted blade coating (bottom pattern). It can be seen in the bottom pattern that the film is mainly composed of intermediate phase with minor perovskite phase. After 70° C. annealing for several minutes, the film transformed into pure perovskite phase with stronger XRD peak intensity than that of the film without DMSO additive, indicating improved crystallinity.

FIG. 15D shows SEM images of as-coated film from a perovskite ink solution using DMSO as solvent and air-knife assisted drying.

FIG. 15E shows SEM images of as-coated film from perovskite ink solution using DMF as solvent and air-knife assisted drying.

FIG. 15F shows SEM images of as-coated film from perovskite ink solution using GBL as solvent and air-knife assisted drying.

FIG. 15G shows SEM images of as-coated film from perovskite ink solution using 2-ME as solvent and air-knife assisted drying.

FIG. 15H shows SEM images of as-coated film from perovskite ink solution using 2-ME/ACN as solvent and air-knife assisted drying.

FIG. 16A shows the J-V curves under one sun illumination for the champion module with aperture area of 57.2 cm². The perovskite thin films were generated using air knife-assisted blading.

FIG. 16B shows that the photocurrent at maximum power output point of 13.6 V bias was ˜63.5 mA, giving the stabilized PCE of 15.1%.

### DETAILED DESCRIPTION

The subject matter described herein relates to new approaches for the formulation of perovskite ink solutions in the fabrication of polycrystalline perovskite films Halide perovskites, such as methylammonium lead halides (i.e., (CH₃NH₃)PbX₃), where CH₃NH₃ corresponds with the methylammonium cation and X is a halogen, are a class of photoactive materials with solar energy applications with device efficiencies exceeding 20%. This class of materials is distinguished by their ABX₃ perovskite crystal structure, wherein A commonly comprises an organic or alkali cation; B often comprises tin or lead; and X is a halide or mixture of halides, such as fluoride, chloride, iodide, or bromide.

One advantage of these materials is that they can be produced and processed at or near room temperature from solution. The ambient-temperature processing and production techniques for these photoactive materials are relatively inexpensive, which is beneficial for their large-scale industrial fabrication. In the conventional fabrication process, precursor perovskite components are mixed in a solvent containing a volatile organic solvent, and the resulting precursor solution is deposited onto a substrate, followed by heating the precursor solution at a temperature sufficient to react and convert the precursor species into the perovskite composition.

However, several challenges and drawbacks exist in applying the conventional volatile organic solvent process. While the high solvent volatility enables rapid crystallization at low temperatures, fast crystallization often results in poor crystallinity and small grain size, which is disadvantageous for photo-generated carriers' transportation and collection in working solar cells, for example. The process is also known to yield films characterized by incomplete coverage of the substrate and inconsistent (non-uniform) film thickness. These characteristics have been shown to hinder device performance

Several research investigations have focused on engineering the perovskite precursor solution by using low or non-volatile solvents as a means to enhance film quality. However, these solvents generally necessitate high pressure or high temperature techniques for uniform application and fast drying of the perovskite inks as a result of the ink's low volatility, high surface tension, and high viscosity. It has also been shown that many of these solvents coordinate strongly with the ions in the precursor ink, thereby inhibiting perovskite formation at room temperature. Proper control of the perovskite crystal growth would enable the production of high-quality polycrystalline perovskite films, thereby enhancing device performance potential.

The inventive process described herein achieves high quality, polycrystalline perovskite films through solvent engineering of the perovskite precursor ink solution. In contrast to the conventional processes, in which the volatility of the solvent in the precursor ink may hinder the perovskite film's production and overall physical properties, the inventive process described herein focuses on both the coordination ability and volatility of solvents in an engineered, mixed solvent system. In the mixed solvent system described herein, mixtures of volatile, non-coordinating solvents (VNCS), and non-volatile, coordinating solvents (NVCS) are applied in the ink solution. As will be described in further detail, the coordinating capability of the solvent refers to the strength of the bonding between the solvent and ionic components of the perovskite ink solution. Mixed solvent systems comprising volatile non-coordinating solvents quickly evaporate after being deposited on a substrate. The quick evaporation of the working solvent allows for the formation of smooth perovskite films at a high speed and at room temperature, but results in small grain size. Surprisingly, the addition of a small amount of a non-volatile coordinating solvent to the mixed solvent system improves the perovskite crystallinity. It is believed that the non-volatile coordinating solvent temporarily remains in the as-coated film in an intermediate phase with the perovskite ink components. The slower release of the non-volatile coordinating solvent under a mild annealing process provides more time and a lower energy barrier for the perovskite crystalline grains to grow larger in size. Thus, by applying the perovskite ink solution using the methods described herein, high quality polycrystalline perovskite films of significant greater quality and with resultant improved photovoltaic properties can be achieved.

The presently disclosed subject matter will now be described more fully hereinafter. However, many modifications and other embodiments of the presently disclosed subject matter set forth herein will come to mind to one skilled in the art to which the presently disclosed subject matter pertains having the benefit of the teachings presented in the foregoing descriptions. Therefore, it is to be understood that the presently disclosed subject matter is not to be limited to the specific embodiments disclosed and that modifications and other embodiments are intended to be included within the scope of the appended claims. In other words, the subject matter described herein covers all alternatives, modifications, and equivalents. Unless otherwise defined, all technical and scientific terms used herein have the same meaning as commonly understood by one of ordinary skill in this field. All publications, patent applications, patents, and other references mentioned herein are incorporated by reference in their entirety. In the event that one or more of the incorporated literature, patents, and similar materials differs from or contradicts this application, including but not limited to defined terms, term usage, described techniques, or the like, this application controls.

I. Definitions

As used herein, “and/or” refers to and encompasses any and all possible combinations of one or more of the associated listed items, as well as the lack of combinations when interpreted in the alternative (“or”).

As used herein, the term “about,” when referring to a measurable value such as an amount of a compound or agent of the current subject matter, dose, time, temperature, and the like, is meant to encompass variations of ±20%, ±10%, ±5%, ±1%, ±0.5%, or even ±0.1% of the specified amount.

The terms “approximately,” “about,” “essentially,” and “substantially” as used herein represent an amount close to the stated amount that still performs a desired function or achieves a desired result. For example, in some embodiments, as the context may dictate, the terms “approximately”, “about”, and “substantially” may refer to an amount that is within less than or equal to 10% of the stated amount. The term “generally” as used herein represents a value, amount, or characteristic that predominantly includes or tends toward a particular value, amount, or characteristic.

As used herein, conditional language used herein, such as, among others, “can,” “could,” “might,” “may,” “e.g.,” and the like, unless specifically stated otherwise or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

As defined herein, “compact” refers to a substantially void-free, densely-packed film.

As defined herein, “pin-hole free” refers to a film that is contiguous and wherein the diameter of any pores within the film are smaller than the thickness of the film. In particular, a substantially pinhole free film is one having a substantially uniform thickness not deviating from film mean thickness by more than +/−0.10%.

As defined herein, “uniform” structure refers to a film characterized by a non-deviating thickness.

As used herein, “contacting” refers to allowing the ink solution to contact the substrate.

As used herein, “VNCS” refers to a volatile, non-coordinating solvent.

As used herein, “NVCS” refers to a non-volatile, coordinating solvent.

As used herein, “VCS” refers to a volatile, coordinating solvent.

As used herein, “NCNCS” refers to a non-volatile, non-coordinating solvent.

As used herein, “2-ME” refers to 2-methoxyethanol.

As used herein, “DMSO” refers to dimethyl sulfoxide.

As used herein, “DMF” refers to dimethylformamide

As used herein, “GBL” refers to y-butyrolactone.

As used herein, “ACN” refers to acetonitrile.

As used herein, “Ac⁻” or “CH₃CO₂⁻” refers to the acetate ion.

As used herein, “SCN′” refers to the thiocyanate ion.

II. Polycrystalline Perovskite Films

The polycrystalline perovskite films described herein have a perovskite composition according to the following formula: ABX₃ (I)

In the above Formula (I), A comprises at least one cation selected from the group consisting of methylammonium, tetramethylammonium, formamidinium, cesium, rubidium, potassium, sodium, butylammonium, phenethylammonium, phenylammonium, and guanidinium.

In certain embodiments, A may comprise an ammonium, an organic cation of the general formula [NR₄]⁺ where the R groups can be the same or different groups. Suitable R groups include, but are not limited to: methyl, ethyl, propyl, butyl, pentyl group or isomer thereof; any alkane, alkene, or alkyne CₓH_{y}, where x=1-20, y=1-42, cyclic, branched or straight-chain; alkyl halides, C_{X}H_{Y}X_{Z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof; any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments, A comprises methylammonium, (CH₃NH₃⁺). In certain embodiments, A is methylammonium. In certain embodiments, A comprises tetramethylammonium, ((CH₃)₄N⁺). In certain embodiments, A comprises butylammonium, which may be represented by (CH₃(CH₂)₃NH₃⁺) for n-butylammonium, by ((CH₃)₃CNH₃+) for t-butylammonium, or by (CH₃)₂CHCH₂NH₃⁺) for iso-butylammonium. In certain embodiments, A comprises phenethylammonium, which may be represented by C₆H₅(CH₂)₂NH₃⁺ or by C₆H₅CH(CH₃)NH₃⁺. In certain embodiments, A comprises phenylammonium, C₆H₅NH₃⁺.

In certain embodiments, A may comprise a formamidinium, an organic cation of the general formula [R₂NCHNR₂]⁺ where the R groups can be the same or different groups. Suitable R groups include, but are not limited to: hydrogen, methyl, ethyl, propyl, butyl, pentyl or an isomer thereof; any alkane, alkene, or alkyne CₓH_{y}, where x=1-20, y=1-42, cyclic, branched or straight-chain; alkyl halides, C_{X}H_{Y}X_{Z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., imidazole, benzimidazole, dihydropyrimidine, (azolidinylidenemethyl)pyrrolidine, triazole); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments A comprises a formamidinium ion represented by (H₂NH-NH₂⁺).

In certain embodiments, A may comprise a guanidinium, an organic cation of the general formula [(R₂N)₂C=NR₂]⁺ where the R groups can be the same or different groups. Suitable R groups include, but are not limited to: hydrogen, methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., octahydropyrimido[1,2-a]pyrimidine, pyrimido[1,2-a]pyrimidine, hexahydroimidazo[1,2-a]imidazole, hexahydropyrimidin-2-imine); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments, A may comprise a guanidinium ion of the type (H₂N═C—(NH₂)₂⁺).

In certain embodiments, A may comprise an alkali metal cation, such as Li⁺, Na⁺, K⁺, Rb⁺, or Cs⁺.

In certain embodiments, the perovskite crystal structure composition may be doped (e.g., by partial substitution of the cation A and/or the metal B) with a doping element, which may be, for example, an alkali metal (e.g., Li⁺, Na⁺, K⁺, Rb⁺, or Cs⁺), an alkaline earth metal (e.g., Mg⁺², Ca⁺², Sr⁺², Ba⁺²) or other divalent metal, such as provided below for B, but different from B (e.g., Sn⁺², Pb²⁺, Zn⁺², Cd⁺², Ge⁺², Ni⁺², Pt⁺², Pd⁺², Hg⁺², Si⁺², Ti⁺²), or a Group 15 element, such as Sb, Bi, As, or P, or other metals, such as silver, copper, gallium, indium, thallium, molybdenum, or gold, typically in an amount of up to or less than about 1, 5, 10, 20, 25, 30, 35, 40, 45, 50, 55, 60, 65, 70, 75, 80, 85, 90, 95, 99, or 100 mol % of A or B. A may comprise a mixture of cations. B may comprise a mixture of cations.

The variable B comprises at least one divalent (B⁺²) metal atom. The divalent metal (B) can be, for example, one or more divalent elements from Group 14 of the Periodic Table (e.g., divalent lead, tin, or germanium), one or more divalent transition metal elements from Groups 3-12 of the Periodic Table (e.g., divalent titanium, vanadium, chromium, manganese, iron, cobalt, nickel, copper, zinc, palladium, platinum, and cadmium), and/or one or more divalent alkaline earth elements (e.g., divalent magnesium, calcium, strontium, and barium). The variable X is independently selected from one or a combination of halide atoms, wherein the halide atom (X) may be, for example, fluoride (F⁻), chloride (Cr), bromide (Br⁻), and/or iodide (I⁻).

In certain embodiments, the crystalline perovskite composition of Formula (I) is selected from the group consisting of cesium lead iodide (CsPbI₃), methylammonium tin iodide (CH₃NH₃SnI₃), cesium tin iodide (CsSnI₃), methylammonium lead iodide (CH₃NH₃PbI₃), cesium lead bromide (CsPbBr₃), methylammonium tin bromide (CH₃NH₃SnBr₃), cesium tin bromide (CsSnBr₃), methylammonium lead bromide, (CH₃NH₃PbBr₃), formamidinium tin bromide (CHNH₂NH₂SnBr₃), formamidinium lead bromide (CHNH₂NH₂PbBr₃), formamidinium tin iodide (CHNH₂NH₂SnI₃), and formamidinium lead iodide (CHNH₂NH₂PbI₃). In certain embodiments, the crystalline perovskite composition of Formula (I) is methylammonium tin iodide (CH₃NH₃SnI₃) or methylammonium lead iodide (CH₃NH₃PbI₃). In certain embodiments, the crystalline perovskite composition of Formula (I) is methylammonium lead iodide (CH₃NH₃PbI₃).

In certain embodiments, the polycrystalline perovskite films described herein have a film thickness in the range of about 10 nm to about 1 cm. In certain embodiments, the polycrystalline perovskite films have a thickness of about 300 nm to about 1000 nm. In certain embodiments, the polycrystalline perovskite films have a thickness in the range of about 80 nm to about 300 nm. In certain embodiments, the polycrystalline perovskite films have a thickness in the range of about 0.1 mm to about 50 mm. In certain embodiments, the polycrystalline perovskite films have a thickness in the range of about 100 nm to about 1000 nm. In certain embodiments, the perovskite films have a film thickness of about, at least, above, up to, or less than, for example, 200 nm, 300 nm, 400 nm, 500 nm, 600 nm, 700 nm, 800 nm, 900 nm, 1000 nm (1 μm), 2 μm, 3 μm, 4 μm, 5μm, 6 μm, 7 μm, 8 μm, 9 μm, or 10 μm.

The polycrystalline perovskite films described herein have an average grain size of about 10 nm to about 1 mm. In certain embodiments, the crystalline perovskite films have an average grain size of about, at least, or above 0.01 μm, 10 μm, 20 μm, 30 μm, 40 μm, 50 μm, 60 μm, 70 μm, 80 μm, 90 μm, 100 μm, 120 μm, 150 μm, 180 μm, 200 μm, 220 μm, 250 μm, 280 μm, 300 μm, 350 μm, 400 μm, 450 μm, 500 μm, 550 μm, 600 μm, 650 μm, 700 μm, 800 μm, 850 μm, 900 μm, 1000 μm, or an average grain size within a range bounded by any two of the foregoing exemplary values. It is generally known in the art that large grain sizes are suitable for films in photoactive or photovoltaic applications.

In certain embodiments, the polycrystalline perovskite films are also capable of achieving compact, pin-hole free, and uniform structures with an area of at least 25 cm². In certain embodiments, the perovskite films produced may have an area of at least 15 cm², 17 cm², 20 cm², 22 cm², 25 cm², 27 cm², 30 cm², 35 cm², 40 cm², 45 cm² , 50 cm², 55 cm², 60 cm², 75 cm², 80 cm², 85 cm², 100 cm², 125 cm², 150 cm², 200 cm², 225 cm², 250 cm², 275 cm², 300 cm², 325 cm², or 350 cm².

III. Ink Solutions

In another aspect, the subject matter described herein is directed to an ink solution. In certain embodiments, the ink solution comprises a compound of formula BX′₂, wherein B is a least one divalent metal and X′ is a monovalent anion; a compound of formula AX, wherein A is at least one monovalent cation selected from the group consisting of methylammonium, tetramethylammonium, formamidinium, guanidinium, cesium, rubidium, potassium, sodium, butylammonium, phenethylammonium, and phenylammonium; X is selected from the group consisting of halide, acetate (CH₃CO₂⁻), and thiocyanate (SCN⁻); and a mixed solvent system comprising two or more solvents selected from the group consisting of dimethyl sulfoxide, dimethylformamide, γ-butyrolactone, 2-methoxyethanol, and acetonitrile.

In certain embodiments, the ink solution comprises a compound of formula BX′₂, wherein the at least one divalent metal (B) is selected from the group consisting of lead, tin, cadmium, germanium, zinc, nickel, platinum, palladium, mercury, titanium, and silicon. In certain embodiments, the ink solution comprises a compound of formula BX′₂, wherein the at least one divalent metal (B) is lead or tin. In certain embodiments, the ink solution comprises a compound of formula BX′₂, wherein the divalent metal (B) comprises lead. In certain embodiments, the ink solution comprises a compound of formula BX′₂, wherein the divalent metal (B) is lead. In certain embodiments, the ink solution comprises a compound of formula BX′₂, further comprising a partial substitution of (B) by a metal selected from the group consisting of lithium, sodium, potassium, cesium, rubidium, magnesium, calcium, strontium, barium, antimony, bismuth, arsenic, phosphorus, gallium, indium, thallium, molybdenum, gold, silver, copper, and combinations thereof. In certain embodiments, the ink solution comprises a compound of formula BX′₂, further comprising a partial substitution of (B) by a metal selected from the group consisting of lithium, sodium, potassium, cesium, rubidium, antimony, bismuth, arsenic, phosphorus, gallium, indium, thallium, molybdenum, gold, silver, copper, and combinations thereof. The dopant element that is partially substituted on the B site may be present in an amount of up to or less than about 1, 5, 10, 20, 25, 30, 35, 40, 45, 50, 55, 60, 65, 70, 75, 80, 85, 90, 95, 99, or 100 mol % of B.

In the compound of formula BX′₂, the monovalent anion X′ can be any anionic species, including halide species X. In certain embodiments, the monovalent anion (X′) is a halide. Some examples of anionic species X′, other than halide species, include formate, acetate, propionate, carbonate, nitrate, sulfate, thiosulfate, oxalate, triflate, cyanate, thiocyanate, acetylacetonate, and 2-ethylhexanoate. Some examples of compounds of formula BX′₂ include the following: lead(II) fluoride, (PbF₂); lead(II) chloride, (PbCl₂); lead(II) bromide, (PbBr₂); lead(II) iodide, (PbI₂); lead(II) acetate, (Pb(CH₃CO₂)₂) or (PbAc₂); lead(II) carbonate, (PbCO₃); lead(II) nitrate, (Pb(NO₃)₂); lead(II) sulfate, (PbSO₄); lead(II) oxalate, (PbC₂O₄); lead(II) triflate, (C₂F₆O₆PbS₂); lead(II) thiocyanate, (Pb(SCN)₂), lead(II) acetylacetonate, (Pb(C₅H₇O₂)₂); lead(II) 2-ethylhexanoate, (Ci₆H₃₀O₄Pb); tin(II) fluoride, (SₙF₂), tin(II) chloride, (SₙCl₂); tin(II) bromide, (SₙBr₂); tin(II) iodide, (SₙI₂); tin(II) acetate, (Sn(CH₃CO₂)₂) or (SnAc₂); tin(II) carbonate, (SnCO₃); tin(II) nitrate, (Sn(NO₃)₂); tin(II) sulfate, (SnSO₄); tin(II) oxalate, (SnC₂O₄); tin(II) triflate, (C₂F₆O₆SnS₂); tin(II) thiocyanate, (Sn(SCN)₂); tin(II) acetylacetonate, (Sn(C₅H₇O₂)₂); tin(II) 2-ethylhexanoate, (C₁₆H₃₀O₄Sn); germanium(II) chloride, (GeCl₂); germanium(II) bromide, (GeBr₂); germanium (II) iodide, (GeI₂); titanium(II) chloride, (TiCl₂); titanium(II) bromide, (TiBr₂); titanium(II) iodide, (TiI₂); titanium(II) acetate, (Ti(CH₃CO₂)₂); magnesium fluoride, (MgF₂); magnesium chloride, (MgCl₂); magnesium bromide, (MgBr₂); magnesium iodide, (MgI₂); magnesium acetate, (Mg(CH₃CO₂)₂); magnesium sulfate, (MgSO₄); calcium fluoride, (CaF₂); calcium chloride, (CaCl₂); calcium bromide, (CaBr₂); calcium iodide, (CaI₂); calcium acetate, (Ca(CH₃CO₂)₂); calcium sulfate (CaSO₄), cadmium (II) chloride (CdCl₂); cadmium (II) bromide (CdBr₂); cadmium (II) iodide (CdI₂); zinc (II) chloride (ZnCl₂); zinc (II) bromide (ZnBr₂); zinc (II) iodide (ZnI₂); platinum (II) chloride (PtCl₂); platinum (II) bromide (PtBr₂); platinum (II) iodide (PtI₂); nickel (II) chloride (NiCl₂); Nickel (II) bromide (NiBr₂); nickel (II) iodide (NiI₂); palladium (II) chloride (PdCl₂); palladium (II) bromide (PdBr₂); palladium (II) iodide (PdI₂); mercury (II) chloride (HgCl₂); mercury (II) bromide (HgBr₂); and mercury (II) iodide (HgI₂).

In certain embodiments, the formula BX′₂ is selected from the group consisting of PbI₂, PbBr₂, PbCl₂, SnI₂, SnBr₂, and SnCl₂. In certain embodiments, the formula BX′₂ is PbI₂ or SnI₂. In certain embodiments, the compound of the formula BX′₂ is PbI₂.

In the formula AX, the cation species A is at least one monovalent cation selected from the group consisting of methylammonium, tetramethylammonium, formamidinium, guanidinium, cesium, rubidium, potassium, sodium, butylammonium, phenethylammonium, and phenylammonium; and X is selected from the group consisting of halide, acetate (CH₃CO₂⁻), and thiocyanate (SCN). In certain embodiments, X is a halide. Several nonlimiting examples of compounds of Formula AX include methylammonium fluoride, methylammonium chloride, methylammonium bromide, methylammonium iodide, tetramethylammonium fluoride, tetramethylammonium chloride, tetramethylammonium bromide, tetramethylammonium iodide, formamidinium chloride, formamidinium bromide, formamidinium iodide, guanidinium fluoride, guanidinium chloride, guanidinium bromide, guanidinium iodide, cesium iodide, cesium bromide, cesium chloride, butylammonium iodide, butylammonium bromide, butylammonium chloride, phenethylammonium iodide, phenethylammonium bromide, phenethylammonium chloride, phenylammonium iodide, phenylammonium bromide, and phenylammonium chloride. In certain embodiments, the compound of formula AX is selected from the group consisting of methylammonium iodide, methylammonium bromide, methylammonium chloride, formamidinium iodide, formamidinium bromide, formamidinium chloride, cesium iodide, cesium bromide, cesium chloride, butylammonium iodide, butylammonium bromide, butylammonium chloride, phenethylammonium iodide, phenethylammonium bromide, phenethylammonium chloride, phenylammonium iodide, phenylammonium bromide, and phenylammonium chloride. In certain embodiments, the compound of formula AX is selected from the group consisting of methylammonium iodide, cesium iodide, formamidinium iodide, butylammonium iodide, phenethylammonium iodide, methylammonium bromide, cesium bromide, formamidinium bromide, butylammonium bromide, and phenethylammonium iodide. In certain embodiments, the compound of formula AX is methylammonium iodide. In certain embodiments, the ink solution comprises a compound of formula AX, further comprising a partial substitution of (A) by a metal selected from the group consisting of lithium, magnesium, calcium, strontium, barium, and combinations thereof. The dopant element that is partially substituted on the A site may be present in an amount of up to or less than about 1, 5, 10, 20, 25, 30, 35, 40, 45, 50, 55, 60, 65, 70, 75, 80, 85, 90, 95, 99, or 100 mol % of A.

In certain embodiments, BX′₂ is PbI₂ and AX is methylammonium iodide. In the ink solution, BX′₂ and AX in the precursor are generally present in a molar ratio of M:X of about 1:3. In the case where X′ is a halide (X), which corresponds with BX′₂being BX₂, then a B:X molar ratio of about 1:3 can be provided by a 1:1 molar ratio of BX₂:AX. In the case where X′ is non-halide (e.g., acetate), then a B:X molar ratio of about 1:3 can be provided by a 1:3 molar ratio of BX′₂:AX.

In certain embodiments, the relative amount of ABX₃ to BX′₂ and AX is about 99:1. In certain embodiments, the relative amount of ABX₃ to BX′₂ and AX is about 80:20, about 70:30, about 50:50, about 30:70, about 20:80, or about 1:99.

The ink solution disclosed herein comprises a mixed solvent system comprising two or more solvents. In certain embodiments, the mixed solvent system comprises two or more solvents selected from the group consisting of dimethyl sulfoxide, dimethylformamide, 2-methoxyethanol, acetonitrile, methanol, propanol, butanol, tetrahydrofuran, pyridine, alkylpyridine, pyrrolidine, chlorobenzene, dichlorobenzene, dichloromethane, 1-methoxypropan-2-ol, 2-methoxy-1-methylethyl acetate, 2-butoxyethanol, 2-butoxyethyl acetate, 2-(propyloxy)ethanol, ethyl 3-ethoxypropionate, glycol ethers, dimethylacetamide, acetone, N,N-dimethylpropyleneurea, and chloroform. In certain embodiments, the mixed solvent system comprises two or more solvents selected from the group consisting of dimethyl sulfoxide, dimethylformamide, y-butyrolactone, 2-methoxyethanol, and acetonitrile. In certain embodiments, the mixed solvent system comprises three or more solvents.

The two or more solvents comprising the mixed solvent system may be classified as coordinating or non-coordinating solvents. The coordinating ability of a solvent, in one aspect, may refer to its strength as a Lewis base. As defined herein, a Lewis base is a compound or ionic species that can donate an electron pair to an acceptor compound. A Lewis acid is a substance that can accept a pair of nonbonding electrons. In one aspect, a “coordinating solvent” is a strong Lewis base, while a “non-coordinating solvent” is a weak Lewis base.

In another aspect, the coordinating ability of a solvent may refer to how well it coordinates or bonds to a metal ion. In certain embodiments described herein, the coordinating ability of a solvent is related to how well it coordinates or bonds to Pb²⁺ or Sn²⁺. In certain embodiments, a coordinating solvent exhibits strong bonding to Pb²⁺ or Sn²⁺. In certain embodiments, a non-coordinating solvent exhibits weak bonding to Pb²⁺ or Sn²+. The donor number (D_{N}) is often used to quantify a solvent's coordination ability. Donor number is defined as the negative enthalpy value for the 1:1 adduct formation between a Lewis base and the standard Lewis acid SbCl₅ (antimony pentachloride), in dilute solution in the non-coordinating solvent 1,2-dichloroethane, which has a donor number of zero. The donor number is typically reported in units of kcal/mol. In certain embodiments, a coordinating solvent has a donor number of at least 20 kcal/mol. In certain embodiments, a coordinating solvent has a donor number in the range of 20 kcal/mol to 25 kcal/mol. In certain embodiments, a coordinating solvent has a donor number greater than 25 kcal/mol. In some embodiments, a non-coordinating solvent has a donor number less than 20 kcal/mol. Acetonitrile, for example, has a donor number of 14.1 kcal/mol. Acetonitrile is therefore classified as a non-coordinating solvent. Dimethyl sulfoxide has a donor number of 29.8 kcal/mol, and is referred to herein as a coordinating solvent.

In certain embodiments, the mixed solvent system comprises two or more solvents selected from the group consisting of volatile coordinating solvents, non-volatile coordinating solvents, volatile non-coordinating solvents, and non-volatile non-coordinating solvents. In certain embodiments, the mixed solvent system comprises two volatile, non-coordinating solvents. In certain embodiments, the mixed solvent system comprises three or more solvents selected from the group consisting of volatile coordinating solvents, non-volatile coordinating solvents, volatile non-coordinating solvents, and non-volatile non-coordinating solvents. In certain embodiments, the mixed solvent system is a ternary solvent system comprising two volatile non-coordinating solvents and one non-volatile coordinating solvent. In certain embodiments, the mixed solvent system is a ternary solvent system comprising two volatile non-coordinating solvents and one volatile coordinating solvent.

In certain embodiments, the ink solutions, the arrays that contain the ink solutions and methods utilize an ink solution comprising about 58.8% by volume of one volatile non-coordinating solvent, about 39.2% by volume of a second volatile, non-coordinating solvent, and about 2% by volume of a coordinating solvent. In certain embodiments, the percent of the coordinating solvent is about 0.01-10.0%, about 0.01-5%, about 0.01-1%, about 0.1-5% by volume, about 0.5-4% by volume, about 1.0-3% by volume, or about 2-2.5% by volume. The coordinating solvent can be a volatile or non-volatile solvent. In certain embodiments, the coordinating solvent is a non-volatile solvent. In certain embodiments, the coordinating solvent is dimethyl sulfoxide.

In certain embodiments, the mixed solvent system comprising two volatile, non-coordinating solvents can be mixed in a volume ratio in a range of about 1:100 to 100:1. In certain embodiments, the two volatile, non-coordinating solvents are acetonitrile and 2-methoxyethanol. In certain embodiments, the solvent solution comprises a volume ratio of acetonitrile to 2-methoxyethanol of 2:1. In certain embodiments, the volume ration of acetonitrile to 2-methoxyethanol is 3:2. In certain embodiments, the ratio is about 4:3, 1:1, 1:2, 2:3, or 3:4. In some embodiments, the volume ratio of acetonitrile to 2-methoxyethanol is from about 1:100 to about 100:1.

In certain embodiments, the mixed solvent system is a ternary mixed solvent system comprising two volatile, non-coordinating solvents and one coordinating solvent, the solvent system comprises 95 to 99.9% by volume of a mixture of two volatile, non-coordinating solvents in any volume ratio ranging from 1:100 to 100:1 and 0.1 to 5% by volume of one coordinating solvent. The coordinating solvent may be volatile or non-volatile. In certain embodiments, the two volatile, non-coordinating solvents are acetonitrile and 2-methoxyethanol and the one coordinating solvent is dimethyl sulfoxide. In certain embodiments, the mixed solvent system comprises about 95-99.9% by volume acetonitrile and 2-methoxyethanol and about 0.1-5% by volume dimethyl sulfoxide. In certain embodiments, the mixed solvent system comprises about 97% by volume acetonitrile and 2-Methoxyethanol and about 3% by volume dimethyl sulfoxide. In certain embodiments, the mixed solvent system comprises about 97.5% by volume acetonitrile and 2-methoxyethanol and about 2.5% by volume dimethyl sulfoxide. In certain embodiments, the mixed solvent system comprises about 98% by volume acetonitrile and 2-methoxyethanol and about 2% by volume dimethyl sulfoxide.

In certain embodiments, the ink solution may also contain additives. Non-limiting examples of additives include L-α-Phosphatidylcholine, methylammonium chloride, and methylammonium hypophosphite. These additives may be added to the precursor solution in molar percentages ranging from 0.01% to about 1.5% relative to the ABX₃ composition. In certain embodiments, the molar percentage is about 0.025%, about 0.5%, about 0.8%, or about 1.0% relative to the ABX₃ composition.

In certain embodiments, the ink solution has a vapor pressure in a range of about 5 to 100 kPa. In certain embodiments, the ink solution has a vapor pressure in a range of about 2 to 80 kPa, about 5 to 70 kPa, about 10 to 60 kPa, about 15 to 50 kPa, about 20 to 40 kPa, about 25 to 40 kPa, about 5 to 15 kPa, about 7 to 10 kPa, about 10 to 20 kPa, or about 8 to 9 kPa.

IV. Methods

In certain embodiments, the subject matter disclosed herein is directed to a method for producing a polycrystalline perovskite film using the ink solutions described above. In certain embodiments, the method comprises: contacting the ink solution using a fast coating process onto a substrate to form a film, wherein the fast coating process is selected from the group consisting of blade coating, slot die coating, shear coating, gravure coating, brush coating, syringe coating, and screen printing.

Utilizing a fast coating process is advantageous because of increased scalability for perovskite device roll-to-roll production, simplicity, and cost effectiveness. Furthermore, fast coating processes also provide advantages due to high-throughput deposition, high material usage, and application onto flexible substrates. In particular, perovskite films and devices fabricated using a fast coating process, such as blade coating, can have advantageously long carrier diffusion lengths (e.g., up to 3 μm thick) due to the dramatically higher carrier mobility in the blade-coated films Such doctor-blade deposition can be utilized for large area perovskite cells fabricated with high volume roll-to-roll production.

In certain embodiments, a device is used in the fast coating process for contacting the ink solution onto the substrate. In the blade coating process, a “blade coater” may be used. As used herein, “blade coater” is synonymous with “doctor blade.” In certain embodiments, doctor blade coating techniques are used to facilitate formation of the polycrystalline perovskite film during the fabrication process.

In certain embodiments, the method for producing a polycrystalline perovskite film using the fast coating process can take place at a temperature between about 25° C. to about 250° C. In certain embodiments, the process takes place at about room temperature (about 25° C.).

In certain embodiments of the fast coating process, the substrate is moving and the device is stationary. In certain embodiments, the device is a doctor blade. In certain aspects, the substrate is moving at a rate of about 2 mm/s relative to the device. In certain aspects, the substrate is moving at a rate of about 20 mm/s relative to the device. In certain aspects, the substrate is moving at a rate of about 40 mm/s relative to the device. In certain aspects, the substrate is moving at a rate of about 99 mm/s relative to the device. In certain aspects, the substrate is stationary and the device moves relative to the substrate. In certain aspects, the device is moving at a rate of about 2 mm/s relative to the substrate. In certain aspects, the device is moving at a rate of about 20 mm/s relative to the substrate. In certain aspects, the device is moving at a rate of about 40 mm/s relative to the substrate. In certain aspects, the device is moving at a rate of about 99 mm/s relative to the substrate.

In certain embodiments, the fast coating process described herein takes place at about 2 to about 15,000 mm/s. In certain embodiments, the fast coating process described herein takes place at about 2 to about 10,000 mm/s. In certain embodiments, the fast coating process described herein takes place at about 2 to about 99 mm/s. In certain embodiments, the fast coating process takes place at least or at about 2 mm/s, 20 mm/s, 40 mm/s, 60 mm/s, 80 mm/s, 99 mm/s, 150 mm/s, 275 mm/s, 500 mm/s, 700 mm/s, 800 mm/s, 900 mm/s, 1000 mm/s, 2000 mm/s, 3000 mm/s, 4000 mm/s, 5000 mm/s, 6000 mm/s, 7000 mm/s, 8000 mm/s, 9000 mm/s, 10,000 mm/s, 11,000 mm/s, 12,000 mm/s, 13,000 mm/s, 14,000 mm/s, or 15,000 mm/s.

In certain embodiments, the distance between the device used in the fast coating process for contacting the ink solution onto the substrate is between about 10 μm and 1 cm. In certain embodiments, the distance between the device and the substrate is between about 150 and about 350 μm. In certain embodiments, the distance between the device and the substrate is between about 200 and about 300 μm. In certain embodiments, the distance between the device and the substrate is about 200 μm, 225 μm, about 250 μm, about 275 μm, or about 300 μm.

In certain embodiments, the methods described herein to produce polycrystalline perovskite films further comprise knife-assisted drying. Knife drying comprises applying a high velocity, low pressure gas to the ink solution to form a perovskite film on the substrate. An advantage of knife drying in the polycrystalline perovskite film production process is that it helps produces uniform and smooth films As used herein, an “air knife,” “N₂ knife,” or “air doctor” may be used to describe the device that performs knife-assisted drying in the perovskite film production process. The knife may have a gas manifold with a plurality of nozzles that direct a high velocity stream of air or other gas at the perovskite ink on the substrate. The gas used in the knife-assisted drying process may be air, nitrogen, argon, helium, oxygen, neon, hydrogen, and a combination thereof.

In certain embodiments, the knife-assisted drying takes place at a temperature of about 25° C. to about 250° C. In certain embodiments, the knife-assisted drying takes place at room temperature (about 25° C.). In certain embodiments, the knife-assisted drying takes place at a temperature of about 50° C. to about 100° C.

In certain embodiments, the knife-assisted drying takes place at a pressure in a range of about 0 to 500 psi. In certain embodiments, the knife-assisted drying takes place at a pressure in a range of about 5 to 400 psi, about 20 to 300 psi, about 50 to 200 psi, about 100 to 150 psi, about 5 to 25 psi, about 5 to 20 psi, about 10 to 20 psi, about 10 to 19 psi, about 12 to 18 psi, about 12-16 psi, or about 13-16 psi. In certain embodiments, the knife-assisted drying takes place at about 14 psi, about 15, psi, about 16 psi, at about 17 psi, at about 18 psi, or at about 19 psi.

In certain embodiments, the knife is angled against the device used in the fast coating process and the substrate to create a unidirectional air flow over the as-coated film for enhanced blowing uniformity. In certain embodiments, the knife is angled 0°, 5°, 10°, 15°, 20°, 25°, 30°, 35°, 40°, 45°, 50°, 55°, 60°, 65°, 70°, 75°, 80°, 90°, 100°, 120°, 150°, 155°, 170°, or 180° against the device or the substrate.

In certain embodiments, after fast coating and/or knife-assisted drying, the film created from the ink solution (while on the substrate) may undergo annealing. The film is annealed at a temperature of at least or above 30° C. for a time period effective to convert the perovskite precursor components in the ink solution to a film of a crystalline halide perovskite within the scope of Formula (I) above. In certain embodiments, annealing employs a temperature of about, at least, above, up to, or less than 40° C., 50° C., 60° C., 70° C., 80° C., 90° C., 100° C., 110° C., 120° C., 130° C., 140° C., 150° C., 160° C., 170° C., 180° C., 190° C., or 200° C., or a temperature within a range bounded by any two of the foregoing values. In various embodiments, annealing may take place in a range of, for example, 30-200° C., 50-150° C., 30-180° C., 30-150° C., 30-140° C., 30-130° C., 30-120° C., 30-110° C., or 30-100° C.

Annealing may take place for a period of time, for example, in a range of about 0 seconds to 400 minutes, about 5 seconds to 30 seconds, about 5 minutes to about 10 minutes, about 10 minutes to 20 minutes, or about 20 minutes to 30 minutes. Annealing can take place for a period of time, for example, of at least 5 seconds, 10 seconds, 20 seconds, 30 seconds, 1, minute, 5 minutes, 10 minutes, 20 minutes, 30 minutes, 60 minutes, 90 minutes, 120 minutes, 180 minutes, 240 minutes, or 360 minutes.

In certain embodiments, the methods described herein produce polycrystalline perovskite films having a film thickness in a range of about 10 nm to about 1 cm. In certain embodiments, the methods described herein produce polycrystalline perovskite films having a film thickness in a range of about 300 nm to about 1000 nm. In certain embodiments, the methods described herein produce polycrystalline perovskite films having a film thickness in a range of about 80 nm to about 300 nm. In certain embodiments, the methods described herein produce polycrystalline perovskite films having a film thickness in a range of about 0.1 mm to about 50 mm. In certain embodiments, the methods described herein produce polycrystalline perovskite films having a film thickness in a range of about 100 nm to about 1000 nm. In certain embodiments, the methods described herein produce polycrystalline perovskite films having a film thickness in a range of about, at least, above, up to, or less than, for example, 200 nm, 300 nm, 400 nm, 500 nm, 600 nm, 700 nm, 800 nm, 900 nm, 1000 nm (1 μm), 2 μm, 3 μm, 4 μm, 5 μm, 6 μm, 7 μm, 8 μm, 9 μm, or 10 μm.

The methods described herein produce polycrystalline perovskite films having an average grain size of about 10 nm to about 1 mm. In certain embodiments, the methods described herein produce polycrystalline perovskite films having an average grain size of about, at least, or above 0.01 μm, 10 μm, 20 μm, 30 μm, 40 μm, 50 μm, 60 μm, 70 μm, 80 μm, 90 μm, 100 μm, 120 μm, 150 μm, 180 μm, 200 μm, 220 μm, 250 μm, 280 μm, 300 μm, 350 μm, 400 μm, 450 μm, 500 μm, 550 μm, 600 μm, 650 μm, 700 μm, 800 μm, 850 μm, 900 μm, 1000 μm, or an average grain size within a range bounded by any two of the foregoing exemplary values. It is generally known in the art that large grain sizes are suitable for films in photoactive or photovoltaic applications.

In certain embodiments, the methods described herein produce polycrystalline perovskite films capable of achieving compact, pin-hole free, and uniform structures with an area of at least 25 cm². In certain embodiments, methods described herein produce polycrystalline perovskite films having an area of at least 15 cm², 17 cm², 20 cm², 22 cm², 25 cm², 27 cm², 30 cm², 35 cm², 40 cm², 45 cm², 50 cm², 55 cm², 60 cm², 75 cm², 80 cm², 85 cm², 100 cm², 125 cm², 150 cm², 200 cm², 225 cm², 250 cm², 275 cm², 300 cm², 325 cm², or 350 cm².

V. Devices

The polycrystalline perovskite films described herein are useful in a variety of photoactive and photovoltaic applications. The perovskite films can be integrated into, for example, photoluminescent devices, photoelectrochemical devices, thermoelectric devices, and photocatalytic devices. Some non-limiting examples in which the polycrystalline perovskite films can be applied include solar cells, solar panels, solar modules, light-emitting diodes, lasers, photodetectors, x-ray detectors, batteries, hybrid PV batteries, field effect transistors, memristors, or synapses.

In certain embodiments, the polycrystalline perovskite film may be employed in active layers of various device architectures. Furthermore, the polycrystalline perovskite film may serve the function(s) of any one or more components of an active layer (e.g., charge transport material, mesoporous material, photoactive material, and/or interfacial material). In some embodiments, the same perovskite films may serve multiple such functions, although in other embodiments, a plurality of perovskite films may be included in a device, each perovskite film serving one or more such functions.

In certain embodiments, the polycrystalline perovskite films as described herein are applied in a device. In certain embodiments, a device may include a first electrode, a second electrode, and an active layer comprising a polycrystalline perovskite film, the active layer disposed at least partially between the first and second electrodes. In some embodiments, the first electrode may be one of an anode and a cathode, and the second electrode may be the other of an anode and cathode.

An active layer according to certain embodiments may include any one or more active layer components, including any one or more of: charge transport material; liquid electrolyte; mesoporous material; photoactive material (e.g., a dye, silicon, cadmium telluride, cadmium sulfide, cadmium selenide, copper indium gallium selenide, gallium arsenide, germanium indium phosphide, semiconducting polymers, other photoactive materials)); and interfacial material. Any one or more of these active layer components may include one or more perovskite films In some embodiments, some or all of the active layer components may be in whole or in part arranged in sub-layers. For example, the active layer may comprise any one or more of: an interfacial layer including interfacial material; a mesoporous layer including mesoporous material; and a charge transport layer including charge transport material. In some embodiments, photoactive material such as a dye may be coated on, or otherwise disposed on, any one or more of these layers. In certain embodiments, any one or more layers may be coated with a liquid electrolyte. Further, an interfacial layer may be included between any two or more other layers of an active layer, and/or between a layer and a coating (such as between a dye and a mesoporous layer), and/or between two coatings (such as between a liquid electrolyte and a dye), and/or between an active layer component and an electrode. Reference to layers herein may include either a final arrangement (e.g., substantially discrete portions of each material separately definable within the device), and/or reference to a layer may mean arrangement during construction of a device, notwithstanding the possibility of subsequent intermixing of material(s) in each layer. Layers may in some embodiments be discrete and comprise substantially contiguous material. In other embodiments, layers may be substantially intermixed (as in the case of, e.g., BHJ, hybrid, and some DSSC cells). In some embodiments, a device may comprise a mixture of these two kinds of layers. In any case, any two or more layers of whatever kind may in certain embodiments be disposed adjacent to each other (and/or intermixedly with each other) in such a way as to achieve a high contact surface area. In certain embodiments, a layer comprising a perovskite film may be disposed adjacent to one or more other layers so as to achieve high contact surface area (e.g., where a perovskite film exhibits low charge mobility). In other embodiments, high contact surface area may not be necessary (e.g., where a perovskite film exhibits high charge mobility).

A device according to some embodiments may optionally include one or more substrates. In some embodiments, either or both of the first and second electrode may be coated or otherwise disposed upon a substrate, such that the electrode is disposed substantially between a substrate and the active layer. The materials of composition of devices (e.g., substrate, electrode, active layer and/or active layer components) may in whole or in part be either rigid or flexible in various embodiments. In some embodiments, an electrode may act as a substrate, thereby negating the need for a separate substrate. In certain embodiments, the components are flexible. In certain embodiments, the electrodes, substrates, active layers, and/or active layers components are coated using a fast coating process described herein.

The ink solution may be deposited by any of the processes well known in the art for depositing liquid films Some examples of film deposition processes, as described above, include blade coating, slot die coating, shear coating, gravure coating, brush coating, syringe coating, and screen printing. In certain embodiments, blade coating is used. The substrate on which the precursor solution is placed can be any useful substrate known in the art, including functional substrates and sacrificial substrates. The substrate can be any substrate that is non-reactive with the precursor ink components, is suitably robust to withstand potential annealing, and is suitable for integration into a photoactive device. The choice of functional substrate is dependent on the end-use application. In some embodiments, the substrate is inorganic, such as, for example, silicon (Si), a metal (e.g., Al, Co, Ni, Cu, Ti, Zn, Pt, Au, Ru, Mo, W, Ta, or Rh, stainless steel, a metal alloy, or combination thereof), a metal oxide (e.g., glass or a ceramic material, such as F-doped indium tin oxide), a metal nitride (e.g., TaN), a metal carbide, a metal silicide, or a metal boride. In other embodiments, the substrate is organic, such as a rigid or flexible heat-resistant plastic or polymer film, or a combination thereof, or multilayer composite thereof. Some of these substrates, such as molybdenum-coated glass and flexible plastic or polymeric film, are particularly suitable for use in photovoltaic applications. The photovoltaic substrate can be, for example, an absorber layer, emitter layer, or transmitter layer useful in a photovoltaic device. The substrate may be porous or non-porous depending on the end use of the perovskite film.

An electrode may be either an anode or a cathode. In some embodiments, one electrode may function as a cathode, and the other may function as an anode. An electrode may constitute any conductive material. Suitable electrode materials may include any one or more of: indium tin oxide or tin-doped indium oxide (ITO); fluorine-doped tin oxide (FTO); cadmium oxide (CdO); zinc indium tin oxide (ZITO); aluminum zinc oxide (AZO); aluminum (Al); gold (Au); copper (Cu); chromium (Cr); calcium (Ca); magnesium (Mg); titanium (Ti); steel; carbon (and allotropes thereof); and combinations thereof.

The devices employing the polycrystalline perovskite films described herein may comprise mesoporous materials. Mesoporous material may include any pore-containing material. In some embodiments, the pores may have diameters ranging from about 1 to about 100 nm; in other embodiments, pore diameter may range from about 2 to about 50 nm. Suitable mesoporous material includes any one or more of: any interfacial material and/or mesoporous material discussed elsewhere herein; aluminum (Al); bismuth (Bi); indium (In); molybdenum (Mo); niobium (Nb); nickel (Ni); silicon (Si); titanium (Ti); vanadium (V); zinc (Zn); zirconium (Zr); an oxide of any one or more of the foregoing metals (e.g., alumina, ceria, titania, zinc oxide, zircona, etc.); a sulfide of any one or more of the foregoing metals; a nitride of any one or more of the foregoing metals; and combinations thereof.

Photoactive material may comprise any photoactive compound, such as any one or more of silicon (in some instances, single-crystalline silicon), cadmium telluride, cadmium sulfide, cadmium selenide, copper indium gallium selenide, gallium arsenide, germanium indium phosphide, one or more semiconducting polymers, and combinations thereof. In certain embodiments, photoactive material may instead or in addition comprise a dye (e.g., N719, N3, other ruthenium-based dyes). In some embodiments, a dye (of whatever composition) may be coated onto another layer (e.g., a mesoporous layer and/or an interfacial layer). Devices according to various embodiments may include one, two, three, or more photoactive compounds. In certain embodiments including multiple dyes or other photoactive materials, each of the two or more dyes or other photoactive materials may be separated by one or more interfacial layers. In some embodiments, multiple dyes and/or photoactive compounds may be at least in part intermixed.

Charge transport material (e.g., charge transport material of charge transport layers) may include solid-state charge transport material (i.e., a colloquially labeled solid-state electrolyte), or it may include a liquid electrolyte and/or ionic liquid. Any of the liquid electrolyte, ionic liquid, and solid-state charge transport material may be referred to as charge transport material. As used herein, “charge transport material” refers to any material, solid, liquid, or otherwise, capable of collecting charge carriers and/or transporting charge carriers. For instance, in PV devices according to some embodiments, a charge transport material may be capable of transporting charge carriers to an electrode.

Charge carriers may include holes (the transport of which could make the charge transport material just as properly labeled “hole transport material”) and electrons. Holes may be transported toward an anode, and electrons toward a cathode, depending upon placement of the charge transport material in relation to either a cathode or anode in a PV or other device. Suitable examples of charge transport material according to some embodiments may include any one or more of: perovskite material; I⁻/I₃⁻; Co complexes; polythiophenes (e.g., poly(3-hexylthiophene) and derivatives thereof, or P3HT); carbazole-based copolymers such as polyheptadecanylcarbazole dithienylbenzothiadiazole and derivatives thereof (e.g., PCDTBT); other copolymers such as polycyclopentadithiophene-benzothiadiazole and derivatives thereof (e.g., PCPDTBT); poly(triaryl amine) compounds and derivatives thereof (e.g., PTAA); Spiro-OMeTAD; fullerenes and/or fullerene derivatives (e.g., C60, PCBM); and combinations thereof. In certain embodiments, charge transport material may include any material, solid or liquid, capable of collecting charge carriers (electrons or holes), and/or capable of transporting charge carriers. Charge transport material of some embodiments therefore may be n- or p-type active and/or semi-conducting material. Charge transport material may be disposed proximate to one of the electrodes of a device. It may in some embodiments be disposed adjacent to an electrode, although in other embodiments an interfacial layer may be disposed between the charge transport material and an electrode. In certain embodiments, the type of charge transport material may be selected based upon the electrode to which it is proximate. For example, if the charge transport material collects and/or transports holes, it may be proximate to an anode so as to transport holes to the anode. However, the charge transport material may instead be placed proximate to a cathode, and be selected or constructed so as to transport electrons to the cathode.

Devices according to various embodiments may optionally include an interfacial layer between any two other layers and/or materials, although devices according to some embodiments need not contain any interfacial layers. Thus, for example, a device may contain zero, one, two, three, four, five, or more interfacial layers. An interfacial layer may include a thin-coat interfacial layer (e.g., comprising alumina and/or other metal-oxide particles, and/or a titania/metal-oxide bilayer, and/or other compounds in accordance with thin-coat interfacial layers). An interfacial layer according to some embodiments may include any suitable material for enhancing charge transport and/or collection between two layers or materials; it may also help prevent or reduce the likelihood of charge recombination once a charge has been transported away from one of the materials adjacent to the interfacial layer. Suitable interfacial materials may include any one or more of: any mesoporous material and/or interfacial material discussed elsewhere herein; Al; Bi; In; Mo; Ni; platinum (Pt); Si; Ti; V; Nb; Zn; Zr, oxides of any of the foregoing metals (e.g., alumina, silica, titania); a sulfide of any of the foregoing metals; a nitride of any of the foregoing metals; functionalized or non-functionalized alkyl silyl groups; graphite; graphene; fullerenes; carbon nanotubes; and combinations thereof (including, in some embodiments, bilayers of combined materials). In some embodiments, an interfacial layer may include a perovskite film.

In certain embodiments, the subject matter described herein is directed to a perovskite solar cell. In certain embodiments, the perovskite solar cell comprises a substrate; a first transport layer disposed on said substrate; a perovskite film as described herein, which is disposed on said first transport layer; a second transport layer disposed on said film; and a conductive electrode disposed on said second transport layer.

The Power Conversion Efficiency (PCE) of the solar cell as described herein ranges from about 13% to about 24%. In certain embodiments, the PCE is at least 14%, 15%, 16%, 17%, 18%, 19%, 20%, or 21%. In certain embodiments, the PCE is 21.3%.

In certain embodiments, the crystalline perovskite films as described herein are applied in a solar module. In certain embodiments, the modules exhibit a PCE of at least 12%, 13%, 14%, 15%, 16%, 17%, 18%, 19%, 20%, or 21%. In certain embodiments, the modules exhibit a PCE of about 15.9%, about 15.8%, or about 16.4%.

In certain embodiments, the modules comprising the crystalline perovskite films as described herein exhibit a temperature coefficient (β_{PCE}) of about −0.08%/° C., −0.09%/° C., −0.10%/° C., −0.11%/° C., −0.12%/° C., −0.13%/° C., −0.14%/° C., −0.15%/° C., −0.16%/° C., −0.17%/° C., −0.18%/° C., −0.19%/° C., or about −0.20%/° C. As described herein, the temperature coefficient of the module may be obtained by measuring its efficiency under AM1.5 G in the temperature range of 25° C. to 85° C.

The subject matter described herein is directed to the following embodiments:
1. An ink solution, comprising a composition of formula (I):

ABX₃ (I)
wherein A comprises at least one cation selected from the group consisting of methylammonium, tetramethylammonium, formamidinium, cesium, rubidium, potassium, sodium, butylammonium, phenethylammonium, phenylammonium, and guanidinium;
B comprises at least one divalent metal; and
X is at least one halide; and
a mixed solvent system comprising two or more solvents selected from the group consisting of dimethyl sulfoxide, dimethylformamide, γ-butyrolactone, 2-methoxyethanol, and acetonitrile.
2. The ink solution of embodiment 1, further comprising a compound of BX′₂ wherein B is a least one divalent metal and X′ is a monovalent anion; a compound of formula AX, wherein A is at least one monovalent cation selected from the group consisting of methylammonium, tetramethylammonium, formamidinium, guanidinium, cesium, rubidium, potassium, sodium, butylammonium, phenethylammonium, and phenylammonium; and X is selected from the group consisting of halide, acetate (CH₃CO₂), and thiocyanate (SCN⁻).
3. The ink solution of embodiment 1 or 2, wherein the relative amount of ABX₃ to BX′₂ and AX is about 99:1.
4. The ink solution of any one of embodiments 1-3, wherein said two or more solvents are acetonitrile and 2-methoxyethanol.
5. The ink solution of any one of embodiments 1-4, wherein said mixed solvent system comprises one or more coordinating solvents selected from the group consisting of dimethyl sulfoxide and dimethylformamide and one or more solvents selected from the group consisting of γ-butyrolactone, 2-methoxyethanol, and acetonitrile.
6. The ink solution of any one of embodiments 1-5, wherein the coordinating solvent is present in an amount of about 0.01 to 10.0% by volume.
7. The ink solution of any one of embodiments 1-6, wherein the coordinating solvent is dimethyl sulfoxide.
8. The ink solution of any one of embodiments 1-7, wherein said mixed solvent system is a ternary mixed solvent system comprising acetonitrile, 2-methoxyethanol, and dimethyl sulfoxide.
9. The ink solution of any one of embodiments 1-8, wherein said ternary mixed solvent system comprises 95-99.9% by volume acetonitrile and 2-methoxyethanol and 0.1-5% by volume dimethyl sulfoxide.
10. The ink solution of any one of embodiments 1-9, wherein the composition of Formula (I) is selected from the group consisting of cesium lead iodide (CsPbI₃), methylammonium tin iodide (CH₃NH₃SnI₃), cesium tin iodide (CsSnI₃), methylammonium lead iodide (CH₃NH₃PbI₃), cesium lead bromide (CsPbBr₃), methylammonium tin bromide (CH₃NH₃SnBr₃), cesium tin bromide (CsSnBr₃), methylammonium lead bromide, (CH₃NH₃PbBr₃), formamidinium tin bromide (CHNH₂NH₂SnBr₃), formamidinium lead bromide (CHNH₂NH₂PbBr₃), formamidinium tin iodide (CHNH₂NH₂SnI₃), and formamidinium lead iodide (CHNH₂NH₂PbI₃).
11. The ink solution of any one of embodiments 1-10, wherein the composition of Formula (I) is methylammonium lead iodide (CH₃NH₃PbI₃).
12. The ink solution of any one of embodiments 1-11, wherein said at least one divalent metal (B) is selected from the group consisting of lead, tin, cadmium, germanium, zinc, nickel, platinum, palladium, mercury, titanium, and silicon.
13. The ink solution of any one of embodiments 1-12, wherein said at least one divalent metal (B) is lead or tin.
14. The ink solution of any one of embodiments 1-13, wherein said divalent metal (B) is lead.
15. The ink solution of any one of embodiments 1-14, further comprising a partial substitution of (B) by a metal selected from the group consisting of lithium, sodium, potassium, cesium, rubidium, magnesium, calcium, strontium, barium, antimony, bismuth, arsenic, phosphorus, gallium, indium, thallium, molybdenum, gold, silver, copper, and combinations thereof.
16. The ink solution of any one of embodiments 1-15, wherein said monovalent anion (X′) is selected from the group consisting of halide, acetate (CH₃CO₂⁻), and thiocyanate (SCN⁻).
17. The ink solution of any one of embodiments 1-16, wherein said compound of the formula BX′₂ is selected from the group consisting of PbI₂, PbBr₂, PbCl₂, Pb(CH₃CO₂)₂, SnI₂, SnBr₂, SnCl₂, and Sn(CH₃CO₂)₂.
18. The ink solution of any one of embodiments 1-17, wherein said compound of the formula BX′₂ is PbI₂.
19. The ink solution of any one of embodiments 1-18, wherein the compound of formula AX is selected from the group consisting of methylammonium iodide, methylammonium bromide, methylammonium chloride, formamidinium iodide, formamidinium bromide, formamidinium chloride, cesium iodide, cesium bromide, cesium chloride, butylammonium iodide, butylammonium bromide, butylammonium chloride, phenethylammonium iodide, phenethylammonium bromide, phenethylammonium chloride, phenylammonium iodide, phenylammonium bromide, and phenylammonium chloride.
20. The ink solution of any one of embodiments 1-19, wherein the compound of formula AX is selected from the group consisting of methylammonium iodide, cesium iodide, formamidinium iodide, butylammonium iodide, phenethylammonium iodide, methylammonium bromide, cesium bromide, formamidinium bromide, butylammonium bromide, and phenethylammonium iodide.
21. The ink solution of any one of embodiments 1-20, wherein the compound of formula AX is methylammonium iodide.
22. The ink solution of any one of embodiments 1-21, further comprising a partial substitution of (A) by a metal selected from the group consisting of lithium, magnesium, calcium, strontium, barium, and combinations thereof.
23. The ink solution of any one of embodiments 1-22, wherein BX'₂ is PbI₂ and AX is methylammonium iodide.
24. The ink solution of any one of embodiments 1-23 having a vapor pressure in a range of about 5 to 100 kPa, for use in a fast coating process, wherein said fast coating process is selected from the group consisting of blade coating, slot die coating, shear coating, gravure coating, brush coating, syringe coating, and screen printing.
25. A method for producing a polycrystalline perovskite film using the ink solution of any one of embodiments 1-24, said method comprising:
contacting said ink solution of any one of embodiments 1-24 using a fast coating process onto a substrate to form a film, wherein said fast coating process is selected from the group consisting of blade coating, slot die coating, shear coating, gravure coating, brush coating, syringe coating, and screen printing.
26. The method of embodiment 25, wherein said contacting of the ink solution onto said substrate using said fast coating process is conducted at about 2 to about 10,000 mm/s.
27. The method of embodiment 25 or 26, wherein said contacting of the ink solution onto said substrate using said fast coating process is conducted at about 40 mm/s.
28. The method of any one of embodiments 25-27, wherein said contacting of the ink solution onto said substrate using said fast coating process is conducted at about 99 mm/s.
29. The method of any one of embodiments 25-28, further comprising annealing said film, wherein a polycrystalline perovskite film having large grain sizes of about 10 nm to 1 mm is prepared.
30. The method of any one of embodiments 25-29, wherein the area of the film produced is at least 25 cm².
31. A film comprising a polycrystalline perovskite composition of formula (I): ABX₃ (I)
wherein A comprises at least one cation selected from the group consisting of methylammonium, tetramethylammonium, formamidinium, cesium, rubidium, potassium, sodium, butylammonium, phenethylammonium, phenylammonium, and guanidinium;
B comprises at least one divalent metal; and
X is at least one halide;
wherein the film of said polycrystalline perovskite composition has large grain sizes in a range of about 10 nm to 1 mm, a thickness in a range of about 10 nm to 1 cm, and a compact, pin-hole free, and uniform structure of at least 25 cm².

32. The film of embodiment 31, wherein the crystalline perovskite composition of Formula (I) is selected from the group consisting of cesium lead iodide (CsPbI₃), methylammonium tin iodide (CH₃NH₃SnI₃), cesium tin iodide (CsSnI₃), methylammonium lead iodide (CH₃NH₃PbI₃), cesium lead bromide (CsPbBr₃), methylammonium tin bromide (CH₃NH₃SnBr₃), cesium tin bromide (CsSnBr₃), methylammonium lead bromide, (CH₃NH₃PbBr₃), formamidinium tin bromide (CHNH₂NH₂SnBr₃), formamidinium lead bromide (CHNH₂NH₂PbBr₃), formamidinium tin iodide (CHNH₂NH₂SnI₃), and formamidinium lead iodide (CHNH₂NH₂PbI₃).
33. The film of embodiment 31 or 32, wherein the crystalline perovskite composition of Formula (I) is methylammonium lead iodide (CH₃NH₃PbI₃).
34. A solar cell, solar panel, light emitting diode, photodetector, x-ray detector, field effect transistor, memristor, or synapse comprising the polycrystalline perovskite film of any one of embodiments 31-33.
35. A perovskite solar cell, comprising:
a substrate;
a first transport layer disposed on said substrate;
the film of any one of embodiments 31-33 disposed on said first transport layer;
a second transport layer disposed on said film; and
a conductive electrode disposed on said second transport layer.
36. A photovoltaic module comprising a plurality of solar cells of embodiment 35, wherein said module exhibits a Power Conversion Efficiency of at least 12%.
37. The photovoltaic module of embodiment 36, wherein said module exhibits a Power Conversion Efficiency of at least 13%.
38. The photovoltaic module of embodiment 36 or 37, wherein said module exhibits a Power Conversion Efficiency of at least 14%.
39. The photovoltaic module of any one of embodiments 36-38, wherein said module exhibits a Power Conversion Efficiency of at least 15%.

The following examples are offered by way of illustration and not by way of limitation.

### EXAMPLES

### Materials

All chemicals were purchased from Sigma Aldrich unless otherwise specified and used without further purification. Methylammonium iodide was purchased from Greatcell Solar. Methylammonium hypophosphite was synthesized according to the procedure demonstrated by Xiao et al. (Energy & Environmental Science 9, 867-872 (2016)).

### Device Characterization

The J-V measurements of the perovskite modules were performed with a Keithley 2400 Source-Meter under simulated AM 1.5 G irradiation produced by a Xenon-lamp-based solar simulator (Oriel SoI3A, Class AAA Solar Simulator). The light intensity was calibrated using a silicon reference cell (Newport 91150V-KG5). The scan rate was 1 V/s for modules and there was no preconditioning before measurement. To measure the long term operational stability of the perovskite module, the module was encapsulated, illuminated by one sun equivalent metal halide lamp, and loaded at maximum power point. To measure the module efficiency at elevated temperatures, the encapsulated module was placed on a large hotplate and the temperatures of the module were measured with an infrared thermometer. The temperature variation over the module's aperture area was less than 5° C. The scanning electron microscopy (SEM) images were obtained using a Quanta 200 PEG environmental scanning electron microscope. The X-ray diffraction (XRD) patterns were obtained using a Rigaku sixth generation MiniFlex X-ray diffractometer.

### Example 1

### Solvent Engineering for Perovskite Ink Solution

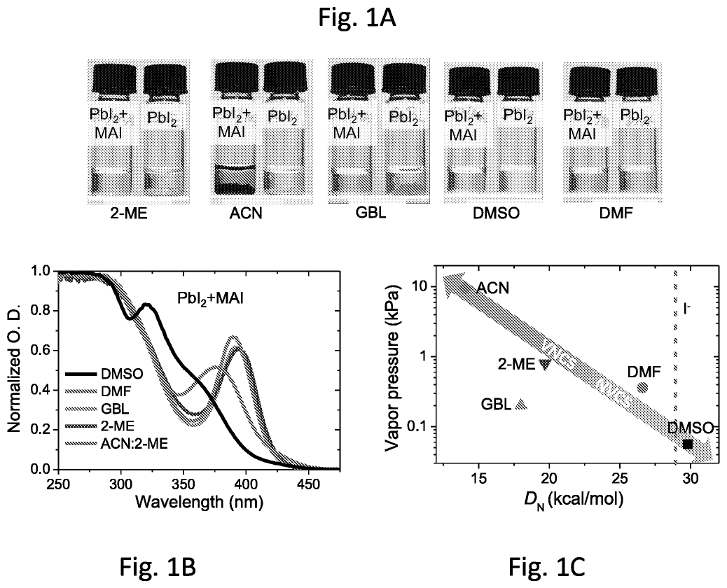

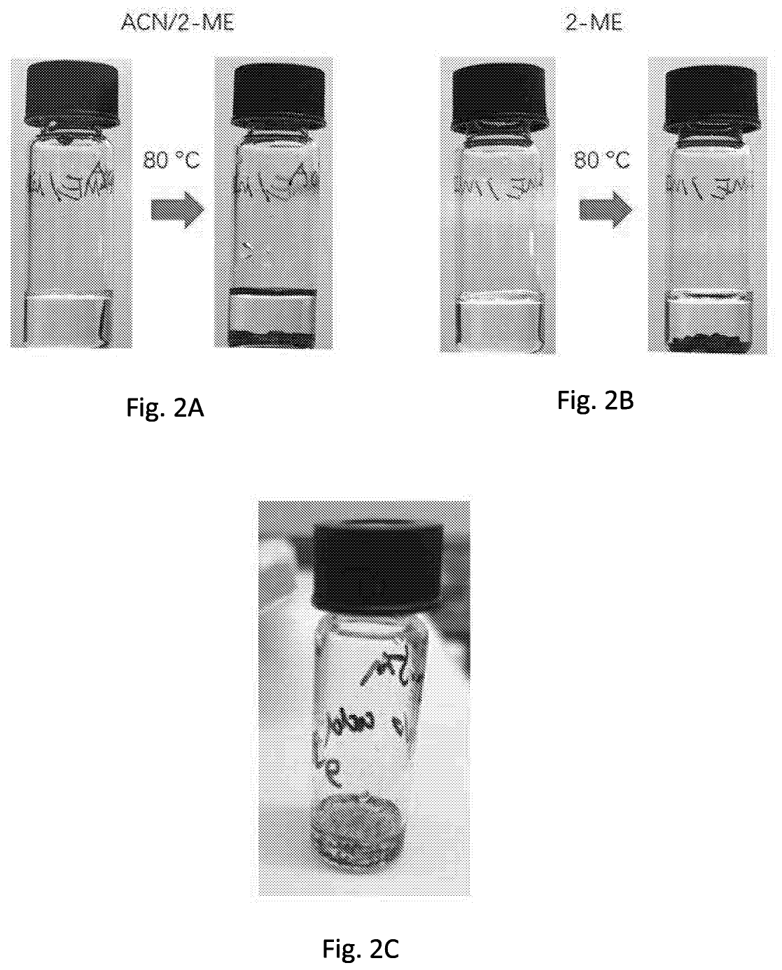

The coordinating ability of dimethyl sulfoxide (DMSO), dimethylformamide (DMF), γ-Butyrolactone (GBL), 2-Methoxyethanol (2-ME), and acetonitrile (ACN) to MAPbI₃ was first investigated.^{10,11} It was discovered that DMSO and DMF could dissolve PbI₂ due to their strong coordination to Pb²⁺ ions,¹² while GBL, 2-ME and ACN could not dissolve PbI₂ unless MAI was added (FIG. 1A). It is understood that only after MAI dissolved, PbI₂ was able to dissolve through I⁻ coordination to Pb²⁺ ions via the formation of PbI₃⁻ complexes, whose characteristic absorption peak at 390 nm was observed for GBL, 2-ME and ACN:2-ME solutions (FIG. 1B).^{12,13} In contrast, much weaker PbI₃⁻ absorption was observed in DMF and DMSO based solutions. Instead of applying only ACN, an ACN:2-ME mixed solvent was used, as it is understood that the solubility of MAPbI₃ in ACN is much lower (<0.1 M) than that in the other solvents. The above experiment demonstrates that DMSO and DMF have strong coordination capability to Pb²⁺, while GBL, 2-ME and ACN:2-ME have either no or much weaker coordination capability. Since the ACN:2-ME mixed solvent exhibited “non-coordinating” behavior, ACN was considered a “non-coordinating” solvent as well. It was further observed that the 2-ME or ACN:2-ME solvent mixture exhibits inverse temperature solubility (FIG. 2A, FIG. 2B, FIG. 2C), which was also observed in GBL, but not in DMF and DMSO.^{14,15} This phenomenon further indicates a weaker coordination ability of GBL, 2-ME or ACN than MM to Pb²⁺, such that MAPbI₃ can precipitate out of the solvent at elevated temperatures.¹⁶ Donor number D_{N} was selected as a figure of merit to describe the solvent's coordination ability to Pb²⁺,¹⁶ The D_{N} of I⁻ ions measured in 1,2-dichloroethane is 28.9 kcal/mol, which is comparable to that of DMF and DMSO, but much larger than 2-ME, ACN, GBL,¹⁶⁻¹⁸ consistent with the results disclosed herein. The D_{N} versus vapor pressures of the five solvents are plotted in FIG. 1C, which shows that 2-ME and ACN can function as VNCS, while DMSO can serve as a NVCS.

### Example 2

### Examination of Solvent Influence on Perovskite Crystallinity using N₂ Knife

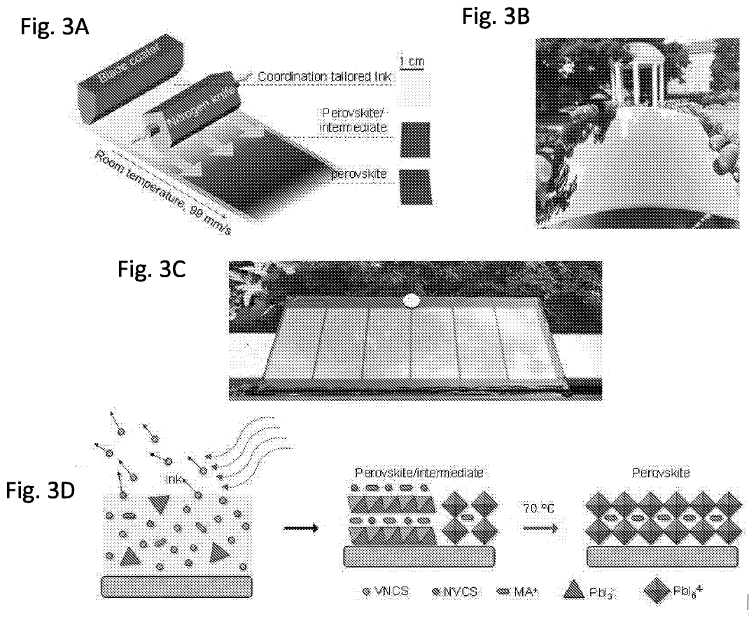

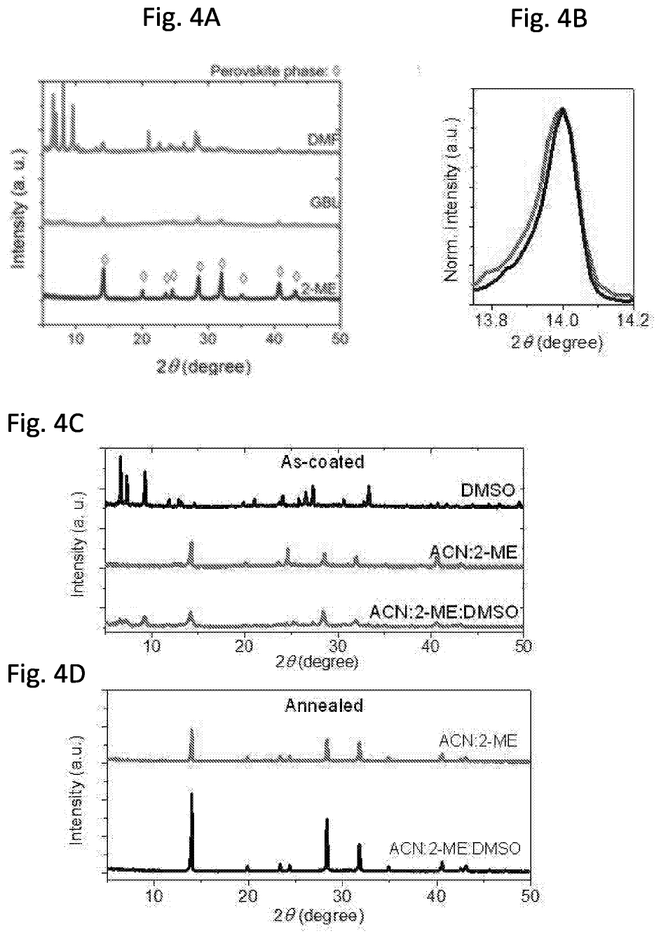

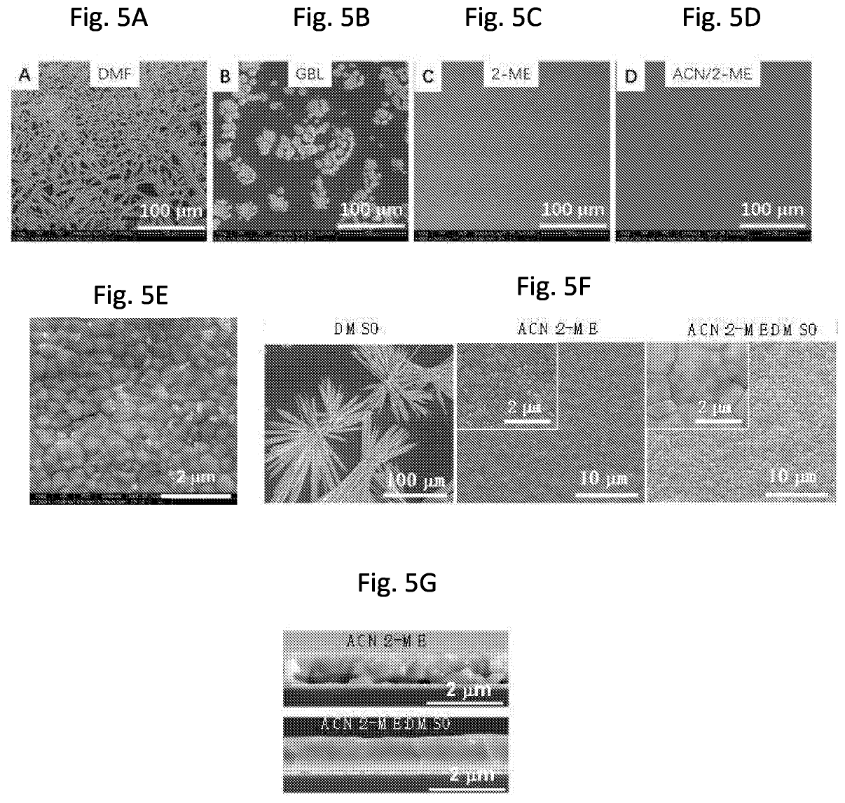

The room temperature N₂-assisted blade coating of the perovskite films using VNCS, NVCS, or a combination of the two was then investigated (FIG. 3A and FIG. 3D). The films coated with 2-ME or ACN:2-ME (3:2 volume ratio) turned black right after coating, exhibiting the pure perovskite phase, as evidenced by the X-ray diffraction patterns (XRD) in FIG. 4A and FIG. 4C. In contrast, when DMSO or DMF was used as a solvent, the films remained wet and required several tens of minutes to dry at room temperature. These films exhibit strong XRD peaks of the intermediate phase below 10°, as a result of DMSO or DMF's strong coordination to the perovskite precursor ink materials. It should be noted that drying of the GBL based solution was also slow, but the as-dried film only exhibits the pure perovskite phase due to its low coordination ability to GBL, like that of 2-ME and ACN. SEM images of the obtained perovskite films are shown in FIG. 5A, FIG. 5B, FIG. 5C, FIG. 5D, and FIG. 5F. The perovskite films coated using solutions of 2-ME or ACN:2-ME solvents are much more compact and uniform, compared with films coated using DMSO, DMF or GBL-based solvents, though the perovskite grain size is only several hundred nanometers. The cross-sectional SEM image of these films (FIG. 5G, top image) shows that these perovskite films have poor physical contact to the PTAA-coated ITO substrate, evidenced by the large voids in between layers. The formation of voids can be explained by earlier solidification at the top of the solution.

Following this, a small amount of NCVS (DMSO) was added to the VNCS hosting solvent. The as-coated films (within several hours after blading) exhibited a mixture of the intermediate phase and the perovskite phase, based on their brown-color (FIG. 3A) and XRD patterns (FIG. 4C). After annealing at 70° C. for 1 min, the films containing the mixed composition transformed into the pure perovskite phase. These perovskite films exhibit stronger and sharper XRD peaks than those formed without DMSO, with full width at half maximum (FWHM) of the (110) peak narrowed from 0.104° to 0.089° (FIG. 4D and 4B). SEM images in FIG. 5F further show that these films are compact and have a large grain size of 1-2 μm in the lateral direction. The cross-sectional SEM image in FIG. 5G (bottom image) indicates that the addition of DMSO also provided the perovskite film with good physical contact to the underlying substrate. Replacing DMSO with GBL, however, resulted in much smaller grain sizes (FIG. 5E), indicating that it is the coordinating ability, rather than the low volatility of DMSO that improves perovskite crystallinity. The intermediate phase formed with the coordinating solvents exhibited a larger lattice constant and more solvent. These characteristics should allow for faster ion transport and therefore a more efficient ripening process during annealing, yielding larger grain sizes.

### Example 3

### Blade Coating Speed Investigations

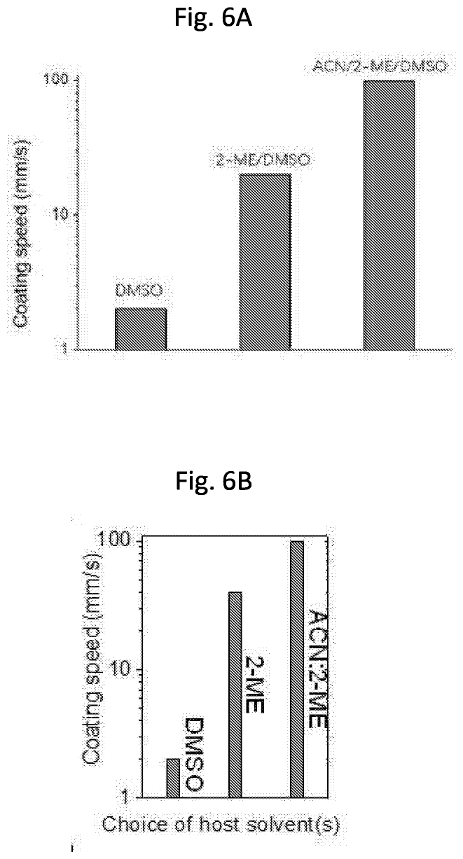

FIG. 6B summarizes the allowed blade coating speeds to form high quality perovskite films with the N₂-knife-assisted blading method using different solvents or solvent mixtures. The N₂-knife was operated under pressures below 20 psi. “High quality” refers to films that are uniform and pin-hole free for module fabrication. Pure DMSO as the solvent required a very slow coating speed, below 2 mm/s. The coating speed increased up to 40 mm/s when using 2-ME as the main solvent. With the addition of ACN at a volume ratio of 3:2 for the ACN:2-ME mixed solvent, the coating speed further increased to 99 mm/s, which was the upper limit speed of the blade coater. Using the latter mixed solvent, a perovskite film was blade coated on a flexible glass substrate with an area of ˜225 cm² at room temperature with a speed of 99 mm/s. For reference, a photographic image of a bladed MAPbI₃ film on a flexible Corning glass with an area of 225 cm² is shown in FIG. 3B.

### Example 4

### Fabrication of Perovskite Modules Using N₂-Knife Assisted Blade-Coated Perovskite Films

Perovskite modules were fabricated using blade-coated, N₂-Knife assisted perovskite films. The device structure was indium tin oxide (ITO)/poly(bis(4-phenyl) (2,4,6-trimethylphenyl) amine (PTAA)/MAPbI₃/fullerene (C₆₀)/Bathocuproine (BCP)/Metal cathode. The PTAA layer was also blade-coated, while the other layers were deposited by thermal evaporation.

### Device Fabrication

Pre-patterned ITO/glass substrates were washed with detergent, deionized water, isopropanol and acetone sequentially and dried in an oven at 60° C. overnight. The PTAA/toluene solution was blade coated on an UV-ozone treated ITO/glass substrate at 20 mm/s with a 200 pm coating gap. The perovskite layer was then blade coated with a nitrogen knife blowing at room temperature. The solution composition was ˜1.0 M MAPbI₃ in a mixture solvent composed of ACN (60% v/v)/2-ME (40% v/v) for coating at 99 mm/s. The molar ratio of DMSO to MAPbI₃ was 20%. L-α-Phosphatidylcholine, methylammonium chloride and methylammonium hypophosphite were added to the solution as additives at molar percentages of ˜0.025%, ˜0.8% and ˜1.0% to MAPbI₃, respectively. The blade coater gap was 200-300 μm. The air knife worked below 20.0 psi. The as-coated solid film was annealed at 70° C. for several minutes and then at 100° C. for 5-20 minutes. Then, the perovskite film was thermally evaporated with C₆₀ (30 nm), BCP (6 nm). Laser scribing was performed twice before and after electrode deposition to complete the module fabrication. For the modules sent for certification, polydimethylsiloxane (PDMS) antireflection (AR) coatings were applied (See Manzoor et al. Solar Energy Materials and Solar Cells 173, 59-65 (2017)).

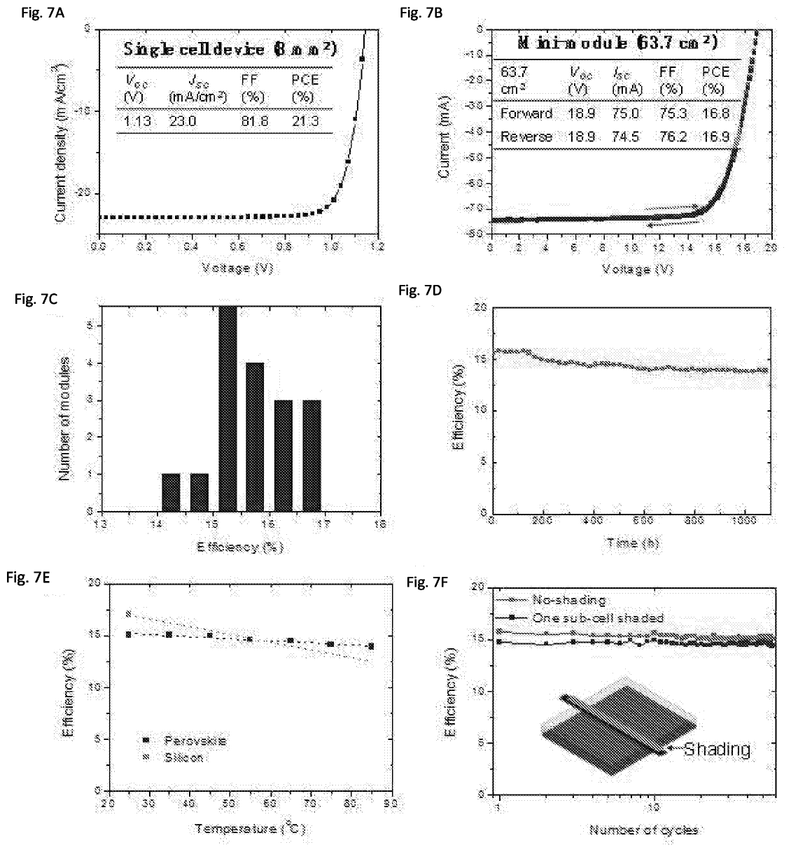

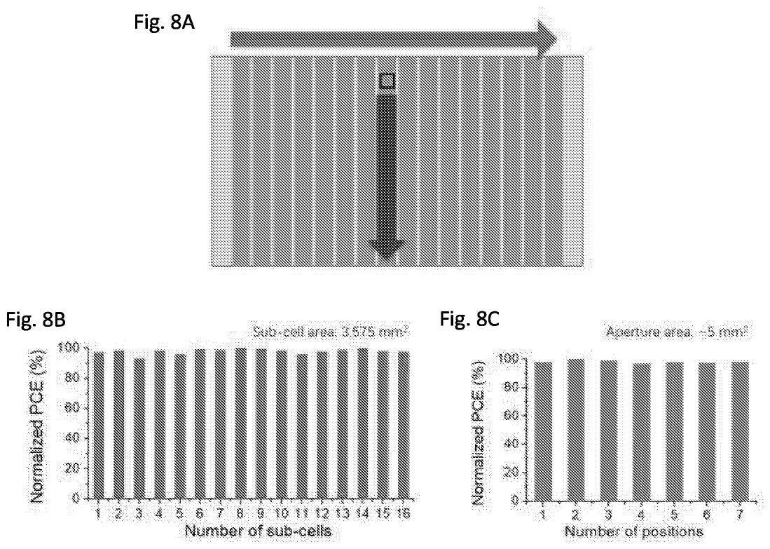

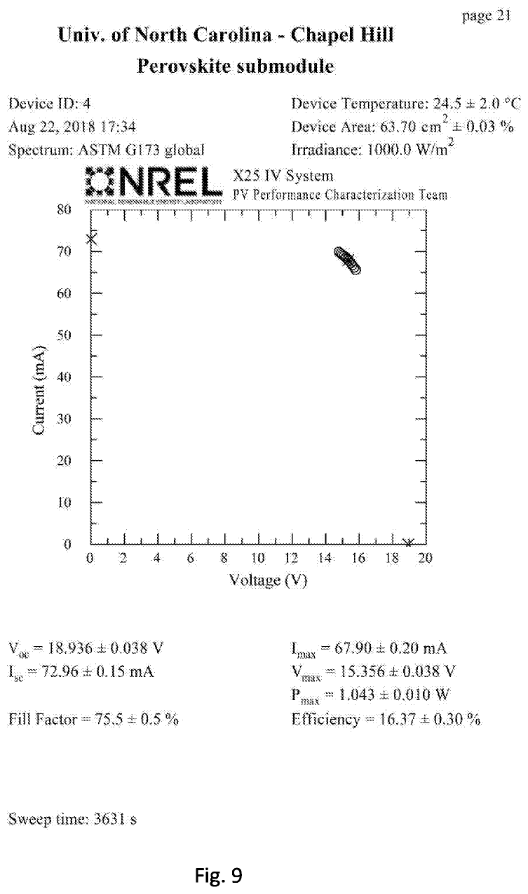

Small area single cells could reach a high PCE of 21.3% with V_{OC} of 1.13 V, J_{SC} of 23.0 mA/cm², and FF of 81.8% (FIG. 7A). These values highlight the advantages of the blading method disclosed herein.²⁰ Large area solar modules were then fabricated. The J-V curves for a champion module under one sun illumination with an aperture area of 63.7 cm² are shown in FIG. 7B, which exhibit little hysteresis. The V_{OC}, I_{SC}, FF and PCE values are summarized in the inserted table. The efficiency statistics of 18 modules fabricated consecutively are summarized in FIG. 7C. Approximately 90% of the modules have efficiencies of 15%-17%, demonstrating high reproducibility.^{7,21} The device uniformity along the lateral direction (parallel to blade coater) and coating direction were then investigated, as shown in FIG. 8A, FIG. 8B, and FIG. 8C. The results indicate that the distribution of the device efficiencies is uniform in both lateral and coating directions. Following this, 5 modules were sent to the National Renewable Energy Laboratory (NREL) for certification. All modules exhibited stabilized efficiencies above 15.9%, with the champion efficiency as 16.4% (FIG. 9). It is noted that the certification was conducted by stabilizing the module around maximum power point (MPP) for 1 hour. The long term operational stability of an encapsulated perovskite module is presented in FIG. 7D. The module was loaded at MPP and its PCEs were measured periodically. After illumination for over 1000 h under 1 sun equivalent light intensity (no UV filter), the module retained 87% of its peak efficiency of 15.8%.

### Example 5

### Temperature Coefficient of Perovskite Module

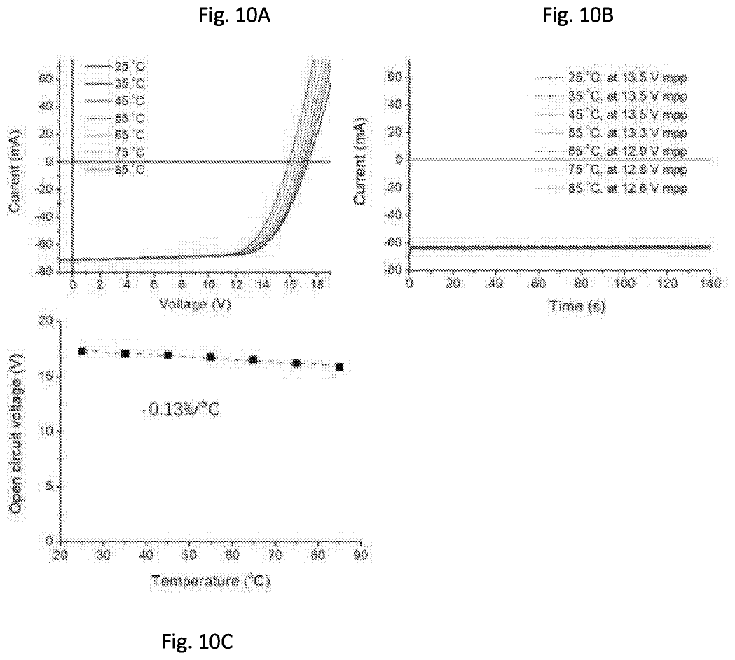

Temperature coefficient β_{PCE} is a parameter that characterizes module efficiency under real working conditions where the temperature can rise above 50° C. Under AM1.5 G illumination, the measured temperature coefficient of the perovskite module in the temperature range of 25° C. to 85° C. was −0.13%/° C. (FIG. 7E). The efficiency loss mainly came from V_{OC}, which had the same coefficient (β_{Voc}) −0.13%/° C., while FF and I_{SC} remained nearly unchanged (FIG. 10A, FIG. 10B, and FIG. 10C). The efficiency of the module remained the same as that before testing when the temperature was reduced to 25° C., excluding degradation of the perovskite modules. This temperature coefficient was smaller than that of CdTe (−0.28%/° C.), CIGS (−0.32%/° C.) and c-Si (−0.44%/° C.),²² as solar cells with larger V_{OC} but comparable E_{g}/q-V_{OC} deficit generally have smaller β_{Voc}.²³ The low temperature coefficient exhibited by the perovskite modules under real operation temperatures above 55° C. (FIG. 7E) appear to be more efficient than silicon modules.

### Example 6

### Shading Tolerance of Perovskite Module

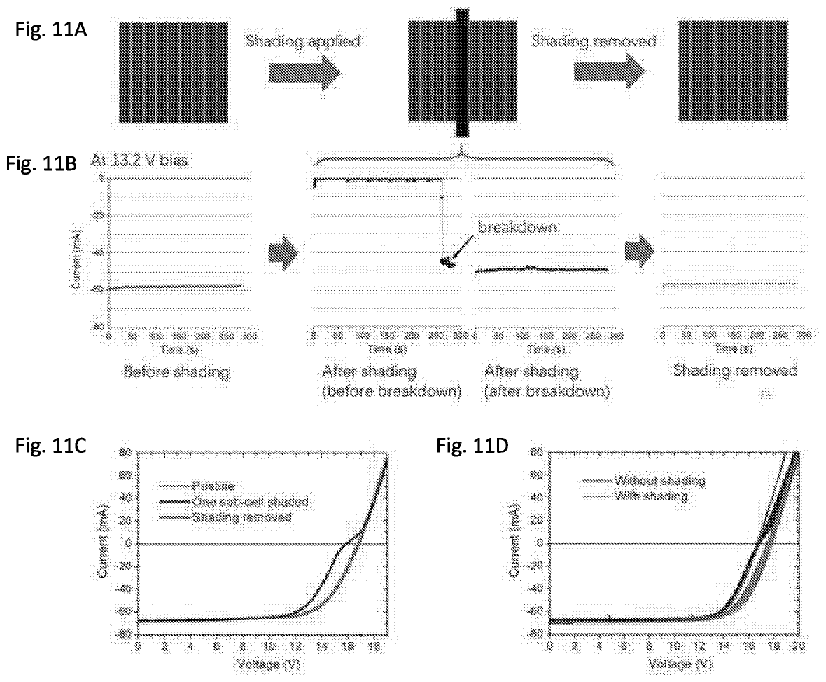

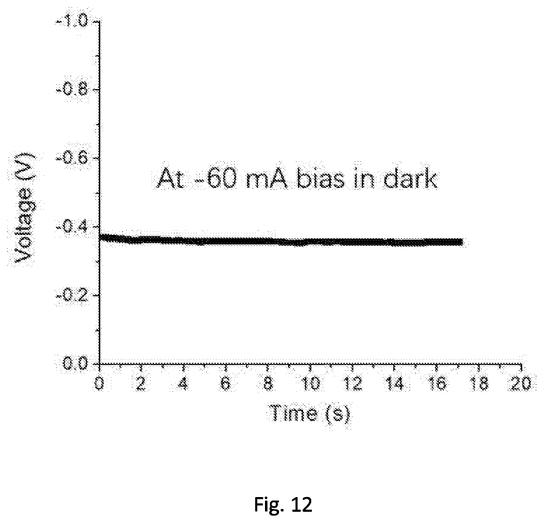

Shading effect is another factor that limits PV module performance in real applications. The shaded sub-cells block the photocurrent of the whole module when sub-cells are connected in series. The shaded sub-cells could be burned by the bias generated from other sub-cells to resume photocurrent output. Silicon solar modules have large breakdown voltages over 15 V,^{25,26} and CdTe and CIGS solar modules have lower breakdown voltage below 10 V. More than 50% of power for those solar modules is lost after breakdown even with shading area of only ˜10%.^{25,26} Additionally, the breakdown results in permanent damage to CdTe and CIGS modules and PCE losses of 4%-14% after 20 s of shading.^{27,28} Here, the extreme case that one sub-cell in the module was entirely shaded while all other sub-cells were exposed to one-sun illumination was mimicked (FIG. 7F, insert). The breakdown of the shaded sub-cell was observed during MPP tracking over 2-4 minutes (FIG. 11A-FIG. 11C). After breakdown, the module resumed its power generation with a small power loss of 6.0 relative %, which is proportional to the nominal area reduction (6.25%). This means that the shaded sub-cell did not negatively affect the remaining sub-cells in the perovskite module. To evaluate the damage, one module was shaded for 4 minutes. The module recovered almost 100% of its original power output when shading was removed, indicating no permanent damage. Over 50 cycles of shading/de-shading were performed on the same sub-cell of a module. A slight reduction of PCE from 15.7% to 15.1% was observed after the first 20 cycles, and then the module PCE stabilized in the following cycles (FIG. 7F and FIG. 11A-FIG. 11C). An investigation on the reverse bias behavior of single perovskite solar cells pointed out that ion migration would induce tunneling breakdown.²⁴ The lack of permanent damage after recovery and low breakdown voltage of ˜0.4 V support this mechanism. Ion migration is a unique property in halide perovskites, which helps explain why perovskite solar modules exhibit good shading tolerance relative to other commercial PV modules.

### Example 7

### Perovskite Module for Charging Cell Phones

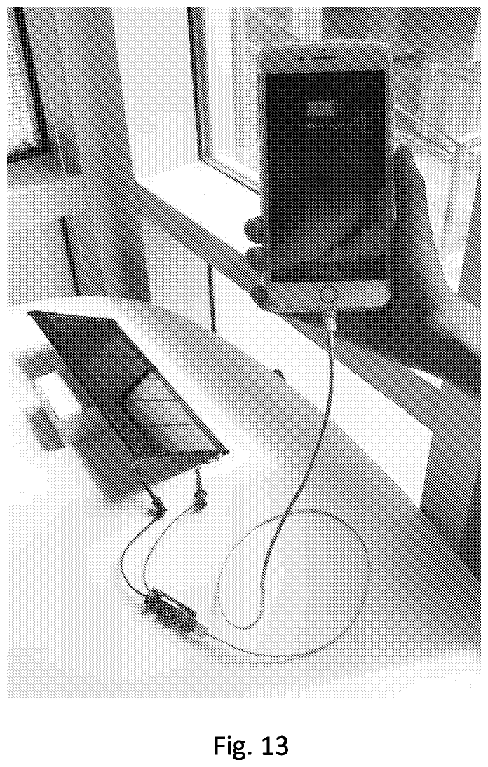

FIG. 3C shows an example of a submodule that was constructed using the perovskite films as produced by the methods disclosed herein. One such perovskite submodule was used for charging cell phones. As shown in FIG. 13, a ˜360 cm² submodule was fabricated with 5-6 W power generation capability, which matches the power output of a cell phone charger, such as an iPhone charger.

### Example 8

### Examination of Solvent Influence on Perovskite Crystallinity using Air Knife

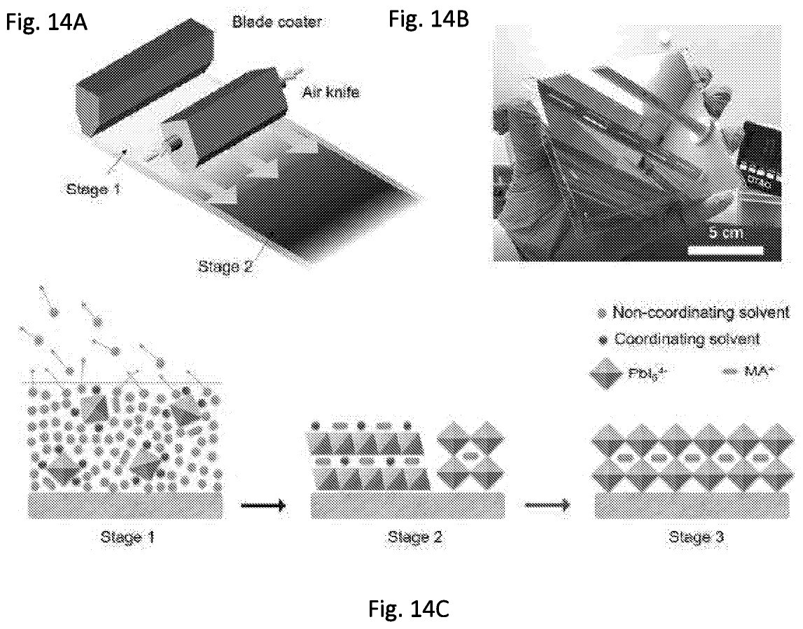

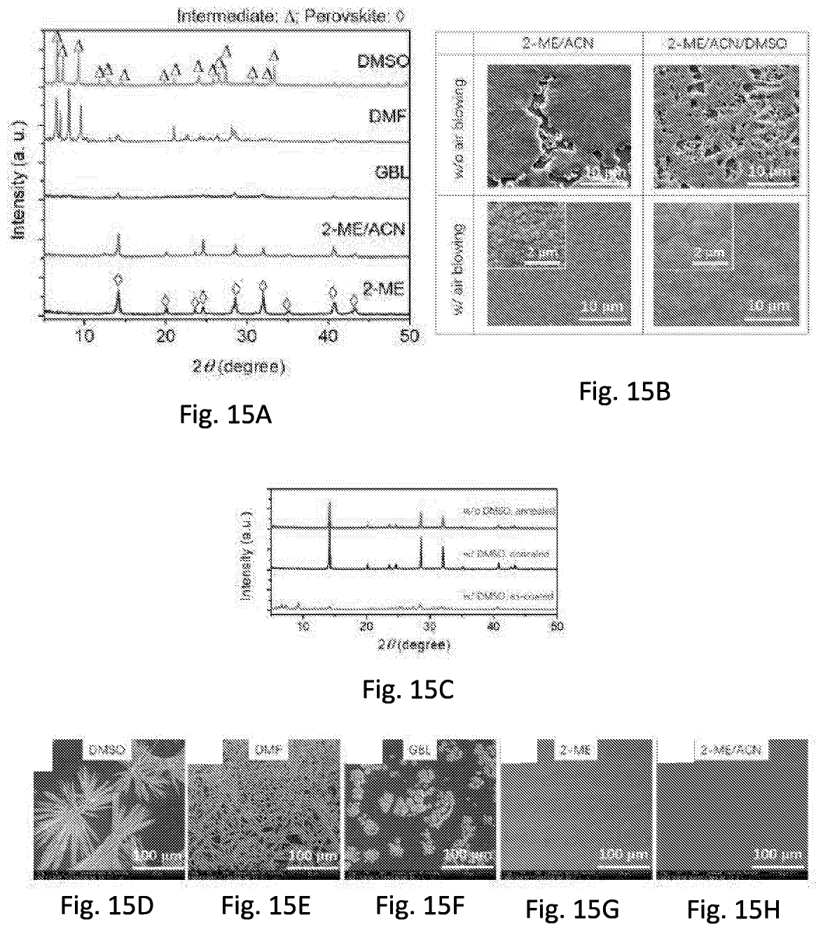

In addition to N₂-assisted fast blading investigations, studies were also conducted with the assistance of an air knife (FIG. 14A, FIG. 14B, and FIG. 14C). It was discovered that when the humidity of the air in the knife was low, there was a negligible difference between perovskite films dried using an air knife or with an N₂ knife. The X-ray diffraction (XRD) patterns of as-obtained film samples dried with an air knife are shown in FIG. 15A. Samples coated from DMSO or DMF solvent show few perovskite phase peaks, but strong peaks of intermediate phase which contain the coordinated solvent molecule. The other samples generated in GBL, 2-ME and ACN/2-ME mixed solvents in a 2:1 volume ratio exhibit the pure perovskite phase.

The perovskite films coated from DMSO, DMF, or GBL solvent do not exhibit as full coverage and high uniformity as those coated with 2-ME or ACN/2-ME based solutions (FIG. 15D-FIG. 15H). Similar to that observed in investigations involving N₂-knife assisted drying, the grains are only several hundred nanometers in size as a result of the short growth duration. As described above, coordinating solvents may inhibit perovskite formation by competing with MAI to coordinate to the Pb²⁺ ions. However, the slow release of a coordinating solvent can promote elongated perovskite crystallization and lead to greater crystallinity. Bearing this in mind, a mixed solvent was prepared using ACN/2-ME as the main solvent, with 2.5% v/v DMS as an additive to the perovskite precursor ink. As shown in FIG. 15C, the as-coated film appears brown and reflective and the XRD pattern shows that the film is mainly composed of the intermediate perovskite phase with some minor perovskite phase also present. After annealing at 70° C. for several minutes, the film transformed into the pure perovskite phase with greater XRD peak intensity than the film generated without the DMSO additive, demonstrating enhanced crystallinity (FIG. 15C). The SEM image in FIG. 15B, lower right shows that the film is smooth and composed of 1-2 μm large grains.

Similar to that demonstrated with N₂ knife-assisted blade coating, fast removal of volatile solvents with the assistance of an air knife can help create uniform and compact perovskite films in the blade coating process. Despite the use of ACN and 2-ME as highly volatile solvents, the air knife promotes solvent evaporation and assists in spreading the perovskite ink over the substrate. As shown in the SEM images in FIG. 15B upper panel, the perovskite films coated without air knife assistance exhibit large gaps and/or pin-holes. FIG. 6A summarizes the allowed blade coating speeds for obtaining high quality perovskite films with air knife assistance as a function of different solvents or solvent compositions. As defined above, “high quality” refers to films that are uniform and pin-hole free for module fabrication. The air knife was operated at a constant pressure of 20 psi. With the addition of ACN at a volume ratio of ACN to 2-ME of 2:1, the coating speed was increased to 99 mm/s, which, as described above, was the upper limit of the blade coater.

### Example 9

### Characterization of Air-Knife Assisted Blade-Coated Perovskite Films in PV Module

A perovskite module was prepared based on a fast bladed, air-knife coated perovskite film. The device structure was indium tin oxide (ITO)/poly(bis(4-phenyl) (2,4,6-trimethylphenyl) amine (PTAA)/MAPbI3/fullerene (C60)/Bathocuproine (BCP)/Chromium/Copper. Pre-patterned ITO/glass substrates were washed with detergent, deionized water, isopropanol and acetone sequentially and dried in an oven at 60° C. overnight. A 3 mg/ml PTAA/toluene solution was blade coated on a UV-ozone treated ITO/glass substrate at 20 mm/s with a 200 μm coating gap and a solution amount of 6 μl/cm (6 μl for every 1 cm width of substrate). Then, the perovskite layer was blade coated with an air knife blowing at room temperature. The modules were coated at 99 mm/s, the solution composition was 0.9 M MAPbI₃ in a mixture solution composed of ACN (65% v/v)/2-ME (32.5% v/v)/DMSO (2.5% v/v). The gap was 300 μm and solution amount was 10 μl/cm. The air knife worked at 20 psi. The as-coated solid film was annealed at 70° C. for several seconds and then at 100° C. for 10 minutes. Following this, the perovskite film was thermally evaporated with C60, BCP, Cr, and Cu sequentially with laser scribing being performed twice after BCP deposition and Cu deposition to complete the module fabrication.

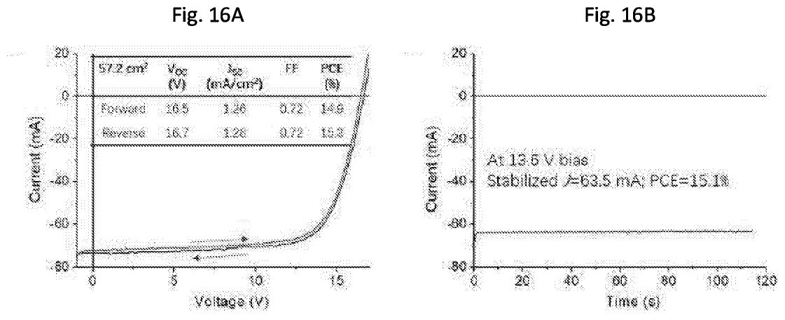

The J-V curves under one sun illumination for the champion module with an aperture area of 57.2 cm² are shown in FIG. 16A, exhibiting little hysteresis. The Voc, Jsc, FF and PCE values are provided in the table in the inset of FIG. 16A. As seen in FIG. 16B, the stabilized photocurrent at maximum power output point of 13.6 V bias was ˜63.5 mA, giving a stabilized PCE of 15.1%.

### REFERENCES

The references listed below as well as all references cited in the specification are incorporated herein by reference to the extent that they supplement, explain, provide a background for or teach methodology, techniques and/or compositions employed herein. All cited patents and publications referred to in this application are herein expressly incorporated by reference.
1 Christians, J. A. et al. Tailored interfaces of unencapsulated perovskite solar cells for >1,000 hour operational stability. Nature Energy 3, 68 (2018).
2 Hou, Y. et al. A generic interface to reduce the efficiency-stability-cost gap of perovskite solar cells. Science 358, 1192-1197 (2017).
3 Tan, H. et al. Efficient and stable solution-processed planar perovskite solar cells via contact passivation. Science 355, 722-726 (2017).
4 Green, M. A. et al. Solar cell efficiency tables (version 50). Progress in Photovoltaics: Research and Applications 25, 668-676 (2017).
5 Li, Z. et al. Scalable fabrication of perovskite solar cells. Nature Reviews Materials 3, 18017 (2018).
6 Rong, Y. et al. Challenges for commercializing perovskite solar cells. Science 361, eaat8235 (2018).
7 Chen, H. et al. A solvent-and vacuum-free route to large-area perovskite films for efficient solar modules. Nature 550, 92 (2017).

8 Mayer, J. N., Philipps, S., Hussein, N. S., Schlegl, T. & Senkpiel, C. Current and future cost of photovoltaics. Long-term scenarios for market development, system prices and LCOE of utility-scale PV systems. Fraunhofer ISE, 1-82 (2015).

9 Schmela, M. Global Market Outlook for Solar Power 2018-2022. SolarPower Europe (2018).

10 Hendriks, K. H. et al. 2-Methoxyethanol as a new solvent for processing methylammonium lead halide perovskite solar cells. Journal of Materials Chemistry A 5, 2346-2354 (2017).

11 Noel, N. K. et al. A low viscosity, low boiling point, clean solvent system for the rapid crystallisation of highly specular perovskite films. Energy & Environmental Science 10, 145-152 (2017).

12 Sharenko, A., Mackeen, C., Jewell, L., Bridges, E & Toney, M. F. Evolution of Iodoplumbate Complexes in Methylammonium Lead Iodide Perovskite Precursor Solutions. Chemistry of Materials 29, 1315-1320 (2017).

13 Stamplecoskie, K. G, Manser, J. S. & Kamat, P. V. Dual nature of the excited state in organic-inorganic lead halide perovskites. Energy & Environmental Science 8, 208-215 (2015).

14 Saidaminov, M. I. et al. High-quality bulk hybrid perovskite single crystals within minutes by inverse temperature crystallization. Nature communications 6, 7586 (2015).

15 Kadro, J. M., Nonomura, K., Gachet, D., Gratzel, M. & Hagfeldt, A. Facile route to freestanding CH 3 NH 3 PbI 3 crystals using inverse solubility. Scientific reports 5, 11654 (2015).

16 Hamill Jr, J. C., Schwartz, J. & Loo, Y.-L. Influence of Solvent Coordination on Hybrid Organic-Inorganic Perovskite Formation. ACS Energy Letters 3, 92-97 (2017).

17 Lau, K. W. et al. Solvent, electrolyte and solute shape effects on optical electron transfer in mixed-valence ruthenium ammine dimers. Inorganica chimica acta 226, 137-143 (1994).

18 Linert, W, Jameson, R. F & Taha, A. Donor numbers of anions in solution: the use of solvatochromic Lewis acid-base indicators. Journal of the Chemical Society, Dalton Transactions, 3181-3186 (1993).

19 Ding, J. et al. Fully Air-Bladed High-Efficiency Perovskite Photovoltaics. Joule, https://doi.org/10.1016/j.joule.2018.1010.1025 (2018).

20 Shin, S. S. et al. Colloidally prepared La-doped BaSnO3 electrodes for efficient, photostable perovskite solar cells. Science 356, 167-171 (2017).

21 Deng, Y. et al. Surfactant-controlled ink drying enables high-speed deposition of perovskite films for efficient photovoltaic modules. Nature Energy, 1 (2018).

22 Fu, E et al. High-efficiency inverted semi-transparent planar perovskite solar cells in substrate configuration. Nature Energy 2, 16190 (2017).

23 Dupre, O., Vaillon, R. & Green, M. Physics of the temperature coefficients of solar cells. Solar Energy Materials and Solar Cells 140, 92-100 (2015).

24 Bowring, A. R., Bertoluzzi, L., O'Regan, B. C. & McGehee, M. D. Reverse Bias Behavior of Halide Perovskite Solar Cells. Advanced Energy Materials 8, 1702365 (2018).

25 Khaing, H. H., Liang, Y. J., Htay, N. N. M. & Fan, J. Characteristics of different solar PV modules under partial shading. Int J Electr Comput Electron Commun Eng 8, 1328-1332 (2014).

26 Tzikas, C. et al. Do thin film PV modules offer an advantage under partial shading conditions? 33rd European Photovoltaic Solar Energy Conference and Exhibition (2017).

27 Silverman, T. J., Deceglie, M. G, Deline, C. & Kurtz, S. in Reliability of Photovoltaic Cells, Modules, Components, and Systems VIII. 95630F (International Society for Optics and Photonics).

28 Silverman, T. J., Mansfield, L., Repins, I. & Kurtz, S. Damage in Monolithic Thin-Film Photovoltaic Modules Due to Partial Shade. IEEE Journal of Photovoltaics 6, 1333-1338 (2016).

Efforts have been made to ensure accuracy with respect to numbers used (e.g., amounts, temperature, etc.) but some experimental errors and deviations should be accounted for.

One skilled in the art will recognize many methods and materials similar or equivalent to those described herein, which could be used in the practicing the subject matter described herein. The present disclosure is in no way limited to just the methods and materials described.

Unless defined otherwise, technical and scientific terms used herein have the same meaning as commonly understood by one of ordinary skill in the art to which this subject matter belongs, and are consistent with: Singleton et al (1994) Dictionary of Microbiology and Molecular Biology, 2nd Ed., J. Wiley & Sons, New York, NY; and Janeway, C., Travers, P., Walport, M., Shlomchik (2001) Immunobiology, 5th Ed., Garland Publishing, New York.

Throughout this specification and the claims, the words “comprise,” “comprises,” and “comprising” are used in a non-exclusive sense, except where the context requires otherwise. It is understood that embodiments described herein include “consisting of” and/or “consisting essentially of” embodiments.

Where a range of values is provided, it is understood that each intervening value, to the tenth of the unit of the lower limit, unless the context clearly dictates otherwise, between the upper and lower limit of the range and any other stated or intervening value in that stated range, is encompassed. The upper and lower limits of these small ranges which may independently be included in the smaller rangers is also encompassed, subject to any specifically excluded limit in the stated range. Where the stated range includes one or both of the limits, ranges excluding either or both of those included limits are also included.

Many modifications and other embodiments set forth herein will come to mind to one skilled in the art to which this subject matter pertains having the benefit of the teachings presented in the foregoing descriptions and the associated drawings. Therefore, it is to be understood that the subject matter is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. An ink solution, comprising a composition of formula (I):
ABX₃ (I)
wherein A comprises at least one cation selected from the group consisting of methylammonium, tetramethylammonium, formamidinium, cesium, rubidium, potassium, sodium, butylammonium, phenethylammonium, phenylammonium, and guanidinium;
B comprises at least one divalent metal; and
X is at least one halide; and
a mixed solvent system comprising two or more solvents selected from the group consisting of dimethyl sulfoxide, dimethylformamide, γ-butyrolactone, 2-methoxyethanol, and acetonitrile.

2. The ink solution of claim 1, further comprising a compound of BX′₂ wherein B is a least one divalent metal and X′ is a monovalent anion; a compound of formula AX, wherein A is at least one monovalent cation selected from the group consisting of methylammonium, tetramethylammonium, formamidinium, guanidinium, cesium, rubidium, potassium, sodium, butylammonium, phenethylammonium, and phenylammonium; and X is selected from the group consisting of halide, acetate (CH₃CO₂⁻), and thiocyanate (SCN⁻).

3. The ink solution of claim 2, wherein the relative amount of ABX₃ to BX′₂ and AX is about 99:1.

4. The ink solution of claim 1, wherein said two or more solvents are acetonitrile and 2-methoxyethanol.

5. The ink solution of claim 1, wherein said mixed solvent system comprises one or more coordinating solvents selected from the group consisting of dimethyl sulfoxide and dimethylformamide and one or more solvents selected from the group consisting of γ-butyrolactone, 2-methoxyethanol, and acetonitrile.

6. The ink solution of claim 5, wherein the coordinating solvent is present in an amount of about 0.01 to 10.0% by volume.

7. The ink solution of claim 6, wherein the coordinating solvent is dimethyl sulfoxide.

8. The ink solution of claim 1, wherein said mixed solvent system is a ternary mixed solvent system comprising acetonitrile, 2-methoxyethanol, and dimethyl sulfoxide.

9. The ink solution of claim 8, wherein said ternary mixed solvent system comprises 95-99.9% by volume acetonitrile and 2-methoxyethanol and 0.1-5% by volume dimethyl sulfoxide.

10. The ink solution of claim 1, wherein the composition of Formula (I) is selected from the group consisting of cesium lead iodide (CsPbI₃), methylammonium tin iodide (CH₃NH₃SnI₃), cesium tin iodide (CsSnI₃), methylammonium lead iodide (CH₃NH₃PbI₃), cesium lead bromide (CsPbBr₃), methylammonium tin bromide (CH₃NH₃SnBr₃), cesium tin bromide (CsSnBr₃), methylammonium lead bromide, (CH₃NH₃PbBr₃), formamidinium tin bromide (CHNH₂NH₂SnBr₃), formamidinium lead bromide (CHNH₂NH₂PbBr₃), formamidinium tin iodide (CHNH₂NH₂SnI₃), and formamidinium lead iodide (CHNH₂NH₂PbI₃).

11. The ink solution of claim 10, wherein the composition of Formula (I) is methylammonium lead iodide (CH₃NH₃PbI₃).

12. The ink solution of claim 1, wherein said at least one divalent metal (B) is selected from the group consisting of lead, tin, cadmium, germanium, zinc, nickel, platinum, palladium, mercury, titanium, and silicon.

13. The ink solution of claim 1, wherein said at least one divalent metal (B) is lead or tin.

14. The ink solution of claim 1, wherein said divalent metal (B) is lead.

15. The ink solution of claim 1, further comprising a partial substitution of (B) by a metal selected from the group consisting of lithium, sodium, potassium, cesium, rubidium, magnesium, calcium, strontium, barium, antimony, bismuth, arsenic, phosphorus, gallium, indium, thallium, molybdenum, gold, silver, copper, and combinations thereof.

16. The ink solution of claim 2, wherein said monovalent anion (X′) is selected from the group consisting of halide, acetate (CH₃CO₂), and thiocyanate (SCIS).

17. The ink solution of claim 2, wherein said compound of the formula BX′₂ is selected from the group consisting of PbI₂, PbBr₂, PbCl₂, Pb(CH₃CO₂)₂, SnI₂, SnBr₂, SnCl₂, and Sn(CH₃CO₂)₂.

18. The ink solution of claim 17, wherein said compound of the formula BX′₂is PbI₂.

19. The ink solution of claim 2, wherein the compound of formula AX is selected from the group consisting of methylammonium iodide, methylammonium bromide, methylammonium chloride, formamidinium iodide, formamidinium bromide, formamidinium chloride, cesium iodide, cesium bromide, cesium chloride, butylammonium iodide, butylammonium bromide, butylammonium chloride, phenethylammonium iodide, phenethylammonium bromide, phenethylammonium chloride, phenylammonium iodide, phenylammonium bromide, and phenylammonium chloride.

20. The ink solution of claim 19, wherein the compound of formula AX is selected from the group consisting of methylammonium iodide, cesium iodide, formamidinium iodide, butylammonium iodide, phenethylammonium iodide, methylammonium bromide, cesium bromide, formamidinium bromide, butylammonium bromide, and phenethylammonium iodide.

21. The ink solution of claim 20, wherein the compound of formula AX is methylammonium iodide.

22. The ink solution of claim 1, further comprising a partial substitution of (A) by a metal selected from the group consisting of lithium, magnesium, calcium, strontium, barium, and combinations thereof.

23. The ink solution of claim 2, wherein BX′₂ is PbI₂ and AX is methylammonium iodide.

24. The ink solution of claim 1 having a vapor pressure in a range of about 5 to 100 kPa, for use in a fast coating process, wherein said fast coating process is selected from the group consisting of blade coating, slot die coating, shear coating, gravure coating, brush coating, syringe coating, and screen printing.

25. A method for producing a polycrystalline perovskite film using the ink solution of claim 1, said method comprising:
contacting said ink solution of claim 1 using a fast coating process onto a substrate to form a film, wherein said fast coating process is selected from the group consisting of blade coating, slot die coating, shear coating, gravure coating, brush coating, syringe coating, and screen printing.

26. The method of claim 25, wherein said contacting of the ink solution onto said substrate using said fast coating process is conducted at about 2 to about 10,000 mm/s.

27. The method of claim 26, wherein said contacting of the ink solution onto said substrate using said fast coating process is conducted at about 40 mm/s.

28. The method of claim 26, wherein said contacting of the ink solution onto said substrate using said fast coating process is conducted at about 99 mm/s.

29. The method of claim 25, further comprising annealing said film, wherein a polycrystalline perovskite film having large grain sizes of about 10 nm to 1 mm is prepared.

30. The method of claim 25, wherein the area of the film produced is at least 25 cm².

31. A film comprising a polycrystalline perovskite composition of formula (I):
ABX₃ (I)
wherein A comprises at least one cation selected from the group consisting of methylammonium, tetramethylammonium, formamidinium, cesium, rubidium, potassium, sodium, butylammonium, phenethylammonium, phenylammonium, and guanidinium;
B comprises at least one divalent metal; and
X is at least one halide;
wherein the film of said polycrystalline perovskite composition has large grain sizes in a range of about 10 nm to 1 mm, a thickness in a range of about 10 nm to 1 cm, and a compact, pin-hole free, and uniform structure of at least 25 cm².

32. The film of claim 31, wherein the crystalline perovskite composition of Formula (I) is selected from the group consisting of cesium lead iodide (CsPbI₃), methylammonium tin iodide (CH₃NH₃SnI₃), cesium tin iodide (CsSnI₃), methylammonium lead iodide (CH₃NH₃PbI₃), cesium lead bromide (CsPbBr₃), methylammonium tin bromide (CH₃NH₃SnBr₃), cesium tin bromide (CsSnBr₃), methylammonium lead bromide, (CH₃NH₃PbBr₃), formamidinium tin bromide (CHNH₂NH₂SnBr₃), formamidinium lead bromide (CHNH₂NH₂PbBr₃), formamidinium tin iodide (CHNH₂NH₂SnI₃), and formamidinium lead iodide (CHNH₂NH₂PbI₃).

33. The film of claim 32, wherein the crystalline perovskite composition of Formula (I) is methylammonium lead iodide (CH₃NH₃PbI₃).

34. A solar cell, solar panel, light emitting diode, photodetector, x-ray detector, field effect transistor, memristor, or synapse comprising the polycrystalline perovskite film of claim 31.

35. A perovskite solar cell, comprising:
a substrate;
a first transport layer disposed on said substrate;
the film of claim 31 disposed on said first transport layer;
a second transport layer disposed on said film; and
a conductive electrode disposed on said second transport layer.

36. A photovoltaic module comprising a plurality of solar cells of claim 35, wherein said module exhibits a Power Conversion Efficiency of at least 12%.

37. The photovoltaic module of claim 36, wherein said module exhibits a Power Conversion Efficiency of at least 13%.

38. The photovoltaic module of claim 36, wherein said module exhibits a Power Conversion Efficiency of at least 14%.

39. The photovoltaic module of claim 36, wherein said module exhibits a Power Conversion Efficiency of at least 15%.
